(19) United States
(12) Patent Application Publication
(10) Pub. No.: US 2026/0082482 A1
(43) Pub. Date: Mar. 19, 2026

(54) MODULE AND ELECTRONIC DEVICE

(71) Applicant: CANON KABUSHIKI KAISHA, Tokyo (JP)

(72) Inventor: NORITAKE TSUBOI, Kanagawa (JP)

(21) Appl. No.: 19/329,967

(22) Filed: Sep. 16, 2025

(30) Foreign Application Priority Data
Sep. 19, 2024 (JP) 2024-162633

(51) Int. Cl. H05K 1/14; H05K 1/18

(52) U.S. Cl. CPC H05K 1/144; H05K 1/181; H05K 2201/041; H05K 2201/10151; H05K 2201/10159; H05K 2201/10719

(57) ABSTRACT

A module includes a wiring member, a first wiring board, and a second wiring board laminated on the first wiring board with the wiring member therebetween. A plurality of first pads bonded to the wiring member via a plurality of first bonding members are disposed on a first main surface of the first wiring board. A plurality of second pads bonded to the wiring member via a plurality of second bonding members are disposed on a second main surface of the second wiring board. The second wiring board has a lower flexural rigidity than the first wiring board. A total area of part of the plurality of second pads in contact with the plurality of second bonding members is larger than a total area of part of the plurality of first pads in contact with the plurality of first bonding members.

### BACKGROUND

### Field of the Technology

The present disclosure relates to a module and an electronic device including the module.

### Description of the Related Art

In the field of electronic devices, increase in the speed of communication of semiconductor devices and increase in the density of layout of the semiconductor devices have progressed, and a technique to three-dimensionally arrange the semiconductor devices and printed wiring boards is used. The semiconductor device is a semiconductor package including a semiconductor element and an interposer, and examples thereof include a digital signal processor and a memory.

A semiconductor device incorporated in an electronic device processes a large amount of data at a high speed. Therefore, the temperature of the semiconductor increases greatly during operation of the semiconductor device, and there is a possibility that stress acting on a bonding portion such as solder increases due to thermal deformation of the semiconductor device and the printed wiring board.

Japanese Patent Application Laid-Open No. 2008-159984 discloses a three-dimensional circuit device in which at least a first circuit board and a second circuit board are interconnected by a three-dimensional inter-board connection structure body constituted by an outer peripheral portion, an inner peripheral portion provided with a recess portion, and a frame-shaped housing.

In a module in which two wiring boards are laminated with a wiring member therebetween, stress can concentrate on a bonding portion between the wiring boards and the wiring member, and improvement in the reliability of the bonding in the module has been desired.

### SUMMARY

The present disclosure provides a technique advantageous for improving the reliability of bonding.

According to one aspect of the present disclosure, a module includes a wiring member, a first wiring board, and a second wiring board laminated on the first wiring board with the wiring member therebetween. A plurality of first pads bonded to the wiring member via a plurality of first bonding members are disposed on a first main surface of the first wiring board. A plurality of second pads bonded to the wiring member via a plurality of second bonding members are disposed on a second main surface of the second wiring board. The second wiring board has a lower flexural rigidity than the first wiring board. A total area of part of the plurality of second pads in contact with the plurality of second bonding members is larger than a total area of part of the plurality of first pads in contact with the plurality of first bonding members.

Features of the present disclosure will become apparent from the following description of embodiments with reference to the attached drawings. The following description of embodiments is described by way of example.

### BRIEF DESCRIPTION OF THE DRAWINGS

FIG. 1 is an explanatory diagram of a digital camera of an example of a digital device according to the first embodiment.

FIG. 2A is a perspective view of a processing module according to the first embodiment.

FIG. 2B is a side view of the processing module according to the first embodiment.

FIG. 3 is a plan view of part of the processing module according to the first embodiment.

FIG. 4A is a section view of the processing module according to the first embodiment.

FIG. 4B is a section view of the processing module according to the first embodiment.

FIG. 5A is a section view of a second wiring board according to the first embodiment.

FIG. 5B is a section view of a wiring member according to the first embodiment.

FIG. 5C is a section view of the wiring member according to the first embodiment.

FIG. 5D is a section view of a first wiring board according to the first embodiment.

FIG. 6A is a section view of a second wiring board according to a first modification example of the first embodiment.

FIG. 6B is a section view of a wiring member according to the first modification example of the first embodiment.

FIG. 6C is a section view of the wiring member according to the first modification example of the first embodiment.

FIG. 6D is a section view of a first wiring board according to the first modification example of the first embodiment.

FIG. 7A is a section view of a second wiring board according to a second modification example of the first embodiment.

FIG. 7B is a section view of a wiring member according to the second modification example of the first embodiment.

FIG. 7C is a section view of the wiring member according to the second modification example of the first embodiment.

FIG. 7D is a section view of a first wiring board according to the second modification example of the first embodiment.

FIG. 8 is a section view of a processing module according to a third modification example of the first embodiment.

FIG. 9 is a section view of a processing module according to a second embodiment.

FIG. 10A is a section view of a second wiring board according to the second embodiment.

FIG. 10B is a section view of a wiring member according to the second embodiment.

FIG. 10C is a section view of the wiring member according to the second embodiment.

FIG. 10D is a section view of a first wiring board according to the second embodiment.

FIG. 11 is a section view of a processing module according to a third embodiment.

FIG. 12A is a section view of a second wiring board according to the third embodiment.

FIG. 12B is a section view of a wiring member according to the third embodiment.

FIG. 12C is a section view of the wiring member according to the third embodiment.

FIG. 12D is a section view of a first wiring board according to the third embodiment.

FIG. 13 is a section view of a processing module according to a fourth embodiment.

FIG. 14A is a section view of a second wiring board according to the fourth embodiment.

FIG. 14B is a section view of a wiring member according to the fourth embodiment.

FIG. 14C is a section view of the wiring member according to the fourth embodiment.

FIG. 14D is a section view of a first wiring board according to the fourth embodiment.

FIG. 15 is a section view of a processing module according to a fifth embodiment.

FIG. 16A is a section view of a second wiring board according to the fifth embodiment.

FIG. 16B is a section view of a wiring member according to the fifth embodiment.

FIG. 16C is a section view of the wiring member according to the fifth embodiment.

FIG. 16D is a section view of a first wiring board according to the fifth embodiment.

FIG. 17 is a graph illustrating results of a thermal fatigue test in first to fourth test examples.

### DESCRIPTION OF THE EMBODIMENTS

Embodiments of the present disclosure will be described in detail below with reference to drawings. To be noted, in each diagram, the same reference signs are used for the same members, and redundant description will be omitted. In the embodiments described below, directions are indicated in an XYZ coordinate system that is an orthogonal coordinate system. The X axis, Y axis, and Z axis are orthogonal to each other. In addition, the direction of the X axis will be also referred to as an X direction, the direction of the Y axis will be also referred to as a Y direction, and the direction of the Z axis will be also referred to as a Z direction. In addition, for example, a positive direction of the X axis indicates a direction indicated by an X-axis arrow in the illustrated coordinate system, and a negative direction of the X axis indicates a direction that is 180° from the direction indicated by the X-axis arrow in the illustrated coordinate system. In addition, in the case where simply an X direction is described, a direction parallel to the X axis is indicated regardless of whether the direction is the same as the direction indicated by the X-axis arrow in the illustration. The same applies to the Y axis and the Z axis other than the X axis. In addition, for example, a plane including the X axis and the Y axis will be expressed as an X-Y plane.

### First Embodiment

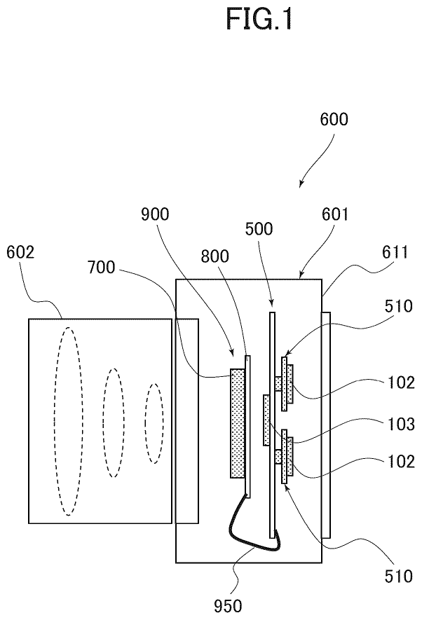

FIG. 1 is an explanatory diagram of a digital camera 600 serving as an example of a system to which a module according to the first embodiment is applied. The digital camera 600 that is an image pickup device is a digital camera of a lens-replacing type in the present example, and includes a camera body 601 that is an electronic device. A lens unit 602 including a lens is attachable to and detachable from the camera body 601. To be noted, the digital camera 600 may be a digital camera of a lens-integrated type in which the camera body 601 and the lens unit 602 are integrated instead of a digital camera of a lens-replacing type. The camera body 601 includes a casing 611, and a processing module 500 and a sensor module 900 that are disposed inside the casing 611. The casing 611 includes a lens mount which the lens unit 602 is attachable to and detachable from. The processing module 500 is an example of a module. The processing module 500 and the sensor module 900 are electrically interconnected by a wiring component 950. The processing module 500 is an example of a first module, and the sensor module 900 is an example of a second module. The wiring component 950 preferably has flexibility (warpability), and is, for example, a flexible printed wiring board or a flexible flat cable.

The sensor module 900 includes an image sensor 700 that is an image pickup device and a printed wiring board 800. The image sensor 700 is mounted on the printed wiring board 800. The image sensor 700 is, for example, a complementary metal oxide semiconductor (CMOS) image sensor or a charge coupled device (CCD) image sensor. The image sensor 700 has a function to convert light incident through the lens unit 602 into an electric signal.

The processing module 500 is an electronic module, and has a three-dimensional mounting structure. The processing module 500 includes a processing device 103 that is an example of a third electronic component. The processing device 103 is a semiconductor device. The processing device 103 is, for example, a digital signal processor. The processing device 103 is an image processing device (image processing engine) having a function to obtain an electric signal from the image sensor 700, perform processing to correct the obtained electric signal, and generate image data.

In addition, the processing module 500 includes a plurality of (for example, four) memories 102. Each memory 102 is an example of an electronic component. Each memory 102 is a semiconductor device. Each memory 102 is, for example, a storage device such as a flash memory or a dynamic random access memory (DRAM) of double data rate 5 (DDR5).

The processing device 103 also functions as a memory controller that controls the memories 102. The processing device 103 can temporarily store the image data in the memories 102, and read out the image data stored in the memories 102.

The processing device 103 and the memories 102 are each a semiconductor package including a semiconductor integrated circuit, and can be, for example, a semiconductor package of an area array such as a ball grid array (BGA) or a land grid array (LGA).

To be noted, although the semiconductor package is preferably one of these kinds, but is not limited to these kinds. For example, as the semiconductor package, various kinds of semiconductor packages such as quad flat package (QFP), quad flat non-leaded package (QFN), quad flat J-leaded package (QFJ), and chip size package (CSP) can be used.

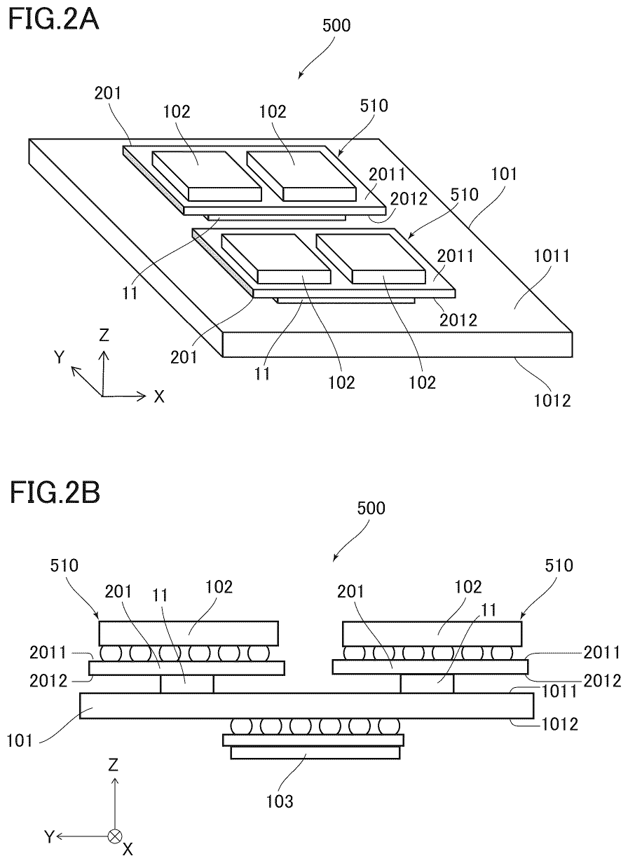

FIG. 2A is a perspective view of the processing module 500 according to the first embodiment, and FIG. 2B is a side view of the processing module 500 according to the first embodiment. The processing module 500 includes a wiring board 101 and two mounting structure bodies 510. The wiring board 101 is an example of a first wiring board. The wiring board 101 is a printed wiring board. The wiring board 101 is, for example, a rigid substrate. The two mounting structure bodies 510 are each mounted on the wiring board 101 via a wiring member 11. By employing such a three-dimensional mounting structure for the processing module 500, the processing module 500 can be miniaturized.

The mounting structure bodies 510 each include a wiring board 201 and two memories 102 mounted on the wiring board 201. The wiring board 201 is an example of a second wiring board. The wiring board 201 is a printed wiring board. The wiring board 201 is, for example, a rigid substrate. The processing module 500 has a three-dimensional mounting structure in which the wiring board 101 and the wiring board 201 are laminated with the wiring member 11 therebetween.

The wiring member 11 is a plate-shaped member. The wiring member 11 is a printed wiring board smaller than the wiring boards 101 and 201. The wiring member 11 is a rigid substrate having a rectangular parallelepiped shape. The wiring member 11 is disposed between the wiring boards 101 and 201, and is used for electrically and mechanically interconnecting the wiring boards 101 and 201. In addition, the wiring member 11 also functions as a spacer between the wiring boards 101 and 201.

The wiring board 101 includes two main surfaces 1011 and 1012. The main surface 1011 is an example of a first main surface. The main surface 1012 is a main surface on the opposite side to the main surface 1011. The main surface 1012 is an example of a sixth main surface. The main surfaces 1011 and 1012 are each a mounting surface on which electronic components can be mounted. The main surfaces 1011 and 1012 have the same area. The two mounting structure bodies 510 are each mounted on the main surface 1011 of the wiring board 101 via the wiring member 11. The processing device 103 is mounted on the main surface 1012 of the wiring board 101. The main surface 1012 is parallel to the main surface 1011. The processing device 103 is surface-mounted on the main surface 1012 of the wiring board 101. The Z direction is a direction orthogonal to the main surface 1011. The X direction and the Y direction are parallel to the main surface 1011. Here, the Z direction is an example of a first direction, the Y direction is an example of a second direction, and the X direction is an example of a third direction. The Y direction is a direction intersecting with the Z direction. The X direction intersects with the Z direction and the Y direction. In the present embodiment, the X direction, Y direction, and Z direction are orthogonal to each other.

The wiring board 201 is a wiring board having a rectangular shape in plan view (that is, as viewed in the Z direction). The longitudinal direction of the wiring board 201 is the X direction, the short-side direction of the wiring board 201 is the Y direction, and the thickness direction of the wiring board 201 is the Z direction. To be noted, the thickness direction of the wiring board 101 and the thickness direction of the wiring member 11 are also the Z direction.

The wiring board 201 includes two main surfaces 2011 and 2012. The main surface 2012 is an example of a second main surface. The main surface 2011 is a main surface on the opposite side to the main surface 2012. The main surface 2011 is an example of a fifth main surface. The main surfaces 2011 and 2012 are each a mounting surface on which electronic components can be mounted. The main surfaces 2011 and 2012 have the same area. The two memories 102 are surface-mounted on the main surface 2011 of the wiring board 201. The size of the wiring board 101 is larger than the size of the wiring board 201. That is, the area of the main surface 1011 of the wiring board 101 is larger than the area of the main surface 2011 of the wiring board 201. Further, the entirety of the wiring board 201 overlaps with the wiring board 101 in the Z direction. In the present embodiment, the two wiring boards 201 are arranged in the Y direction on the main surface 1011 with an interval therebetween in the Y direction such that the long sides of each wiring board 201 are parallel to the X direction.

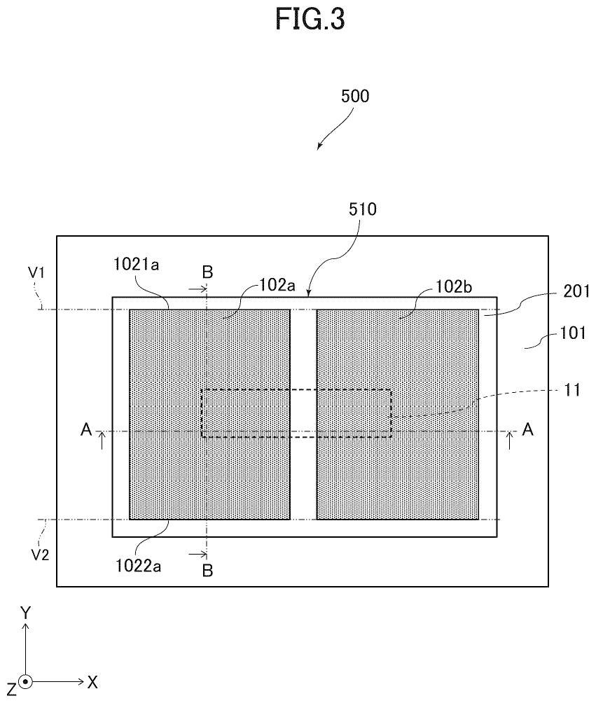

FIG. 3 is a plan view of part of the processing module 500 according to the first embodiment. FIG. 3 illustrates part of the processing module 500 in a case where the processing module 500 is viewed in the −Z direction toward the main surface 1011 of the wiring board 101. FIG. 3 illustrates one of the two mounting structure bodies 510, and illustration of the other is omitted.

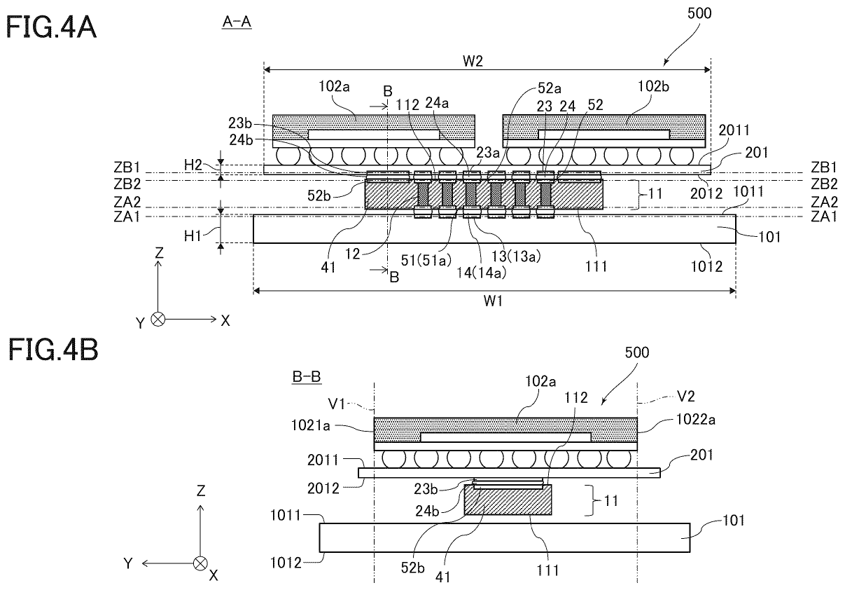

FIGS. 4A and 4B are each a section view of the processing module 500 according to the first embodiment. FIG. 4A schematically illustrates the processing module 500 in a case where a cross-section of the processing module 500 taken along a virtual plane A-A illustrated in FIG. 3 is viewed in the +Y direction. The virtual plane A-A is a virtual plane parallel to the X-Z plane. FIG. 4B schematically illustrates the processing module 500 in a case where a cross-section of the processing module 500 taken along a virtual plane B-B illustrated in FIG. 3 is viewed in the +X direction. The virtual plane B-B is a virtual plane parallel to the Y-Z plane.

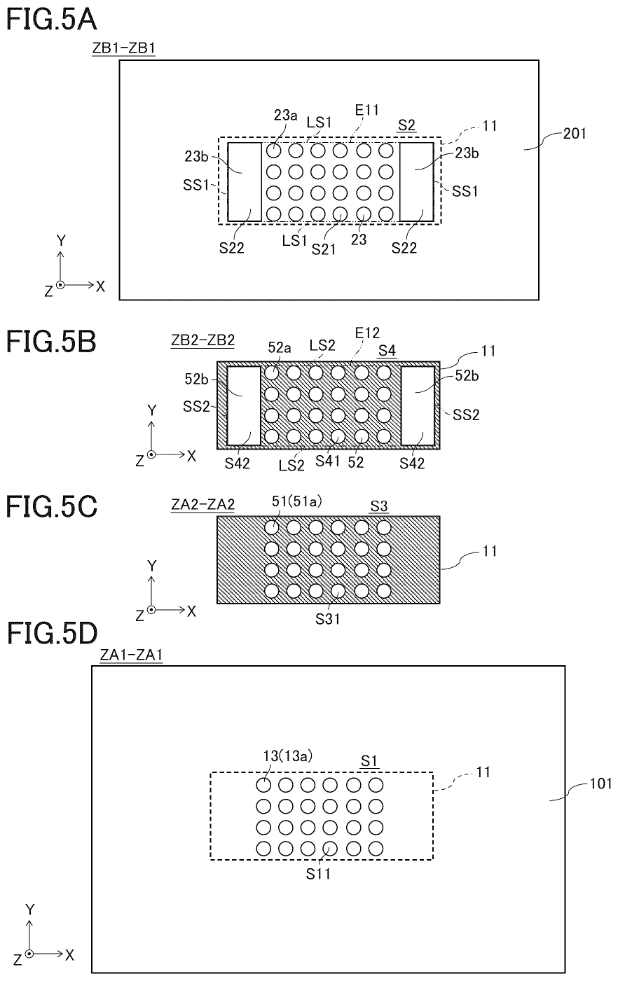

FIG. 5A is a section view of the wiring board 201 according to the first embodiment. FIG. 5B is a section view of the wiring member 11 according to the first embodiment. FIG. 5C is a section view of the wiring member 11 according to the first embodiment. FIG. 5D is a section view of the wiring board 101 according to the first embodiment. FIG. 5A schematically illustrates the wiring board 201 in a case where a cross-section of the wiring board 201 taken along a virtual plane ZB1-ZB1 illustrated in FIG. 4A is viewed in the −Z direction. FIG. 5B schematically illustrates the wiring member 11 in a case where a cross-section of the wiring member 11 taken along a virtual plane ZB2-ZB2 illustrated in FIG. 4A is viewed in the −Z direction. FIG. 5C schematically illustrates the wiring member 11 in a case where a cross-section of the wiring member 11 taken along a virtual plane ZA2-ZA2 illustrated in FIG. 4A is viewed in the −Z direction. FIG. 5D schematically illustrates the wiring board 101 in a case where a cross-section of the wiring board 101 taken along a virtual plane ZA1-ZA1 illustrated in FIG. 4A is viewed in the −Z direction.

A lamination structure of one mounting structure body 510 and the wiring board 101 will be described below. One of the two memories 102 included in the mounting structure body 510 will be referred to as an electronic component 102a, and the other will be referred to as an electronic component 102b. The electronic component 102a is an example of a first electronic component, and the electronic component 102b is an example of a second electronic component.

The electronic components 102a and 102b are arranged in the X direction at an interval in the X direction and thus mounted on the main surface 2011 of the wiring board 201. The wiring member 11 includes a main surface 111 provided on the side to be bonded to the main surface 1011 of the wiring board 101, and a main surface 112 provided on the side to be bonded to the main surface 2012 of the wiring board 201. The main surface 111 is an example of a third main surface. The main surface 112 is a main surface on the opposite side to the main surface 111. The main surface 112 is an example of a fourth main surface. The main surface 111 is a bonding surface to be bonded to the wiring board 101, and the main surface 112 is a bonding surface to be bonded to the wiring board 201. The main surface 111 of the wiring member 11 is bonded to the main surface 1011 of the wiring board 101 via a plurality of bonding members 14, and the main surface 112 of the wiring member 11 is bonded to the main surface 2012 of the wiring board 201 via a plurality of bonding member 24. The plurality of bonding members 14 are each formed from solder. In addition, the plurality of bonding member 24 are each formed from solder.

Here, the main surfaces 1011, 1012, 2011, 2012, 111, and 112 are substantially parallel to each other. Therefore, the direction orthogonal to the main surface 1011 of the wiring board 101 is substantially the same as the direction orthogonal to the main surface 1012 of the wiring board 101, the direction orthogonal to the main surface 2011 of the wiring board 201, the direction orthogonal to the main surface 2012 of the wiring board 201, the direction orthogonal to the main surface 111 of the wiring member 11, and the direction orthogonal to the main surface 112 of the wiring member 11.

The Z direction is also a direction in which the processing module 500 is viewed in plan view. In addition, viewing in the Z direction, that is, viewing in plan view also includes seeing through in the Z direction. In addition, the expression “in the Z direction” can also include “as viewed in the Z direction”. In addition, the X direction is also the longitudinal direction of the wiring member 11, the Y direction is also the short-side direction of the wiring member 11, and the Z direction is also the thickness direction of the wiring member 11. In addition, the Z direction is also the thickness direction of the wiring board 101.

The wiring board 101 includes a plurality of pads 13 disposed on the main surface 1011. The pad 13 is an example of a first pad. The wiring board 201 includes a plurality of pads 23 disposed on the main surface 2012. The pad 23 is an example of a second pad. In addition, the wiring member 11 includes a plurality of pads 51 disposed on the main surface 111 and a plurality of pads 52 disposed on the main surface 112. The pad 51 is an example of a third pad, and the pad 52 is an example of a fourth pad.

The plurality of pads 13 of the wiring board 101 and the plurality of pads 51 of the wiring member 11 are bonded to each other respectively via the plurality of bonding members 14. The plurality of pads 23 of the wiring board 201 and the plurality of pads 52 of the wiring member 11 are bonded to each other respectively via the plurality of bonding members 24. The bonding member 14 is an example of a first bonding member, and the bonding member 24 is an example of a second bonding member.

The plurality of pads 13 of the wiring board 101 are provided in the same number as the plurality of pads 51 of the wiring member 11. The plurality of pads 23 of the wiring board 201 are provided in the same number as the plurality of pads 52 of the wiring member 11. The plurality of pads 13 of the wiring board 101 are each bonded to corresponding one of the plurality of pads 51 of the wiring member 11 via corresponding one of the plurality of bonding members 14. The plurality of pads 23 of the wiring board 201 are each bonded to corresponding one of the plurality of pads 52 of the wiring member 11 via corresponding one of the plurality of bonding members 24.

The surface of each of the plurality of pads 13 of the wiring board 101 is exposed through an opening portion formed in a solder resist (not illustrated). The plurality of pads 13 each may be a solder mask defined (SMD) pad or a non-solder mask defined (NSMD) pad, and are each an SMD pad in the first embodiment.

In addition, the surface of each of the plurality of pads 23 of the wiring board 201 is exposed through an opening portion formed in a solder resist (not illustrated). The plurality of pads 23 each may be an SMD pad or an NSMD pad, and are each an SMD pad in the first embodiment.

In addition, the surface of each of the plurality of pads 51 of the wiring member 11 is exposed through an opening portion formed in a solder resist (not illustrated). The plurality of pads 51 each may be an SMD pad or an NSMD pad, and are each an SMD pad in the first embodiment.

In addition, the surface of each of the plurality of pads 52 of the wiring board 11 is exposed through an opening portion formed in a solder resist (not illustrated). The plurality of pads 52 each may be an SMD pad or an NSMD pad, and are each an SMD pad in the first embodiment.

In the first embodiment, the number of the plurality of pads 23 of the wiring board 201 is larger than the number of the plurality of pads 13 of the wiring board 101. In the example of FIGS. 5A and 5D, the number of the plurality of pads 23 is twenty-six, and the number of the plurality of pads 13 is twenty-four. In addition, the number of the plurality of pads 52 of the wiring member 11 is larger than the number of the plurality of pads 51 of the wiring member 11. In the example of FIGS. 5B and 5C, the number of the plurality of pads 52 is twenty-six, and the number of the plurality of pads 51 is twenty-four. Further, the number of the plurality of bonding members 24 is larger than the number of the plurality of bonding members 14.

The plurality of pads 23 of the wiring board 201 include two or more (two in the first embodiment) pads 23b that do not overlap with any of the plurality of pads 13 of the wiring board 101 in the Z direction. Among the plurality of pads 23, a plurality of pads other than the two pads 23b will be referred to as pads 23a. In the example of FIG. 5A, twenty-four (6×4) pads 23a are provided.

Here, as illustrated in FIG. 5A, a rectangular region E11 of the smallest area enclosing the plurality of pads 23 is defined. The region E11 is an example of a first smallest rectangular region. The outer periphery of the region E11 includes two long sides LS1 extending in the X direction and apart from each other in the Y direction, and two short sides SS1 extending in the Y direction and apart from each other in the X direction.

The two pads 23b are each in contact with at least one (both in the first embodiment) of the two long sides LS1 of the region E11. In addition, the two pads 23b are each in contact with one of the two short sides SS1 of the region E11. Further, the two pads 23b are respectively disposed at far ends in the plurality of pads 23a in the X direction.

The plurality of pads 52 of the wiring member 11 include two or more (two in the first embodiment) pads 52b that do not overlap with any of the plurality of pads 51 of the wiring member 11 in the Z direction. Among the plurality of pads 52, a plurality of pads other than the two pads 52b will be referred to as pads 52a. In the example of FIG. 5B, twenty-four (6×4) pads 52a are provided.

The plurality of pads 13 each overlap with corresponding one of the plurality of pads 51 in the Z direction. The plurality of pads 51 each overlap with corresponding one of the plurality of pads 52a in the Z direction. The plurality of pads 52a each overlap with corresponding one of the plurality of pads 23a in the Z direction. In addition, the two pads 52b each overlap with corresponding one of the two pads 23b in the Z direction.

Here, as illustrated in FIG. 5B, a rectangular region E12 of the smallest area enclosing the plurality of pads 52 is defined. The region E12 is an example of a second smallest rectangular region. The outer periphery of the region E12 includes two long sides LS2 extending in the X direction and apart from each other in the Y direction, and two short sides SS2 extending in the Y direction and apart from each other in the X direction.

The two pads 52b are each in contact with at least one (both in the first embodiment) of the two long sides LS2 of the region E12. In addition, the two pads 52b are each in contact with one of the two short sides SS2 of the region E12. Further, the two pads 52b are respectively disposed at far ends in the plurality of pads 52a in the X direction.

The plurality of bonding members 24 include two bonding members 24b respectively corresponding to the two pads 23b. In addition, the plurality of bonding members 24 include a plurality of bonding members 24a respectively corresponding to the plurality of pads 23a.

That is, each of the two pads 23b is bonded to corresponding one of the two pads 52b via corresponding one of the two bonding members 24b. In addition, each of the plurality of pads 23a is bonded to corresponding one of the plurality of pads 52a via corresponding one of the plurality of bonding members 24a. To be noted, each of the plurality of pads 13 is bonded to corresponding one of the plurality of pads 51 via corresponding one of the plurality of bonding members 14.

The two pads 23b are pads for reinforcement and respectively disposed on two sides in the longitudinal direction (X direction) of the wiring board 201 with respect to the plurality of pads 23a. Similarly, the two pads 52b are pads for reinforcement and respectively disposed on two sides in the X direction with respect to the plurality of pads 52a. The two pads 24b are pads for reinforcement and respectively disposed on two sides in the X direction with respect to the plurality of pads 24a.

The wiring member 11 includes an insulator 41 and a plurality of through hole conductors 12. The insulator 41 has a plurality of through holes formed to penetrate the insulator 41 in the Z direction, and the plurality of through hole conductors 12 are respectively disposed in the plurality of through holes. The plurality of pads 51 are each electrically connected to corresponding one of the plurality of pads 52a via corresponding one of the plurality of through hole conductors 12. That is, the pads 51 and pads 52a are disposed at respective ends of the through hole conductors 12 in the Z direction.

The through hole conductor 12 is used as a signal line, a power supply line, or a grounding line. Among the plurality of pads 13, pads used as a signal line, a power supply line, or a grounding line will be referred to as pads 13a. To be noted, in the first embodiment, all of the plurality of pads 13 are pads 13a used as a signal line, a power supply line, or a grounding line. Among the plurality of pads 51, pads used as a signal line, a power supply line, or a grounding line will be referred to as pads 51a. To be noted, in the first embodiment, all of the plurality of pads 51 are pads 51a used as a signal line, a power supply line, or a grounding line. Among the plurality of bonding members 14, bonding members used as a signal line, a power supply line, or a grounding line will be referred to as bonding members 14a. To be noted, in the first embodiment, all of the plurality of bonding members 14 are bonding members 14a used as a signal line, a power supply line, or a grounding line.

To be noted, in the first embodiment, the two pads 52b are not electrically connected to any of the plurality of pads 51, but may be electrically connected to any of the plurality of pads 51.

The through hole conductor 12 is formed by, for example, plating a through hole formed in the insulator 41 with metal such as copper (Cu). To be noted, although the through hole conductor 12 may have a hollow inside, the configuration is not limited to this, and the inside of the through hole conductor 12 may be filled with an insulating resin or a conductive resin. In addition, the through hole conductor 12 may be formed by filling the through hole formed in the insulator 41 with metal such as copper (Cu).

The insulator 41 is formed from a resin material such as FR4 formed from glass epoxy. To be noted, the insulating material constituting the insulator 41 is not limited to a resin material as long as the material is electrically insulating, and may be an inorganic material such as ceramics.

The wiring boards 101 and 201 are each a multilayer substrate including an insulating substrate formed from a resin material such as FR4 formed from glass epoxy, and a plurality of wiring layers including wiring formed from metal such as copper (Cu).

In the first embodiment, the wiring board 201 is a wiring board having a lower flexural rigidity than the wiring board 101. Further, as a result of the electronic components 102a and 102b having a linear expansion coefficient different from the linear expansion coefficient of the wiring board 201 being mounted on the wiring board 201, the wiring board 201 is more likely to be deformed than the wiring board 101.

In the plurality of pads 13 of the wiring board 101, the total area (bonding area) of a portion that comes into contact with the plurality of bonding members 14 will be denoted by S1. In addition, in the plurality of pads 23 of the wiring board 201, the total area (bonding area) of a portion that comes into contact with the plurality of bonding members 24 will be denoted by S2. The total area S1 is an example of a first total area, and the total area S2 is an example of a second total area. In the first embodiment, S1<S2 holds, that is, the total area S2 is larger than the total area S1.

As a result of the relationship of S1<S2, the wiring board 201 having a relatively low flexural rigidity as compared with the wiring board 101 is reinforced by the plurality of bonding members 24 having a larger bonding area than the plurality of bonding members 14, and thus warpage of the wiring board 201 in the thermal fatigue test is reduced. Since the warpage of the wiring board 201 is reduced, the stress acting on the plurality of bonding members 24a is reduced. In addition, as a result of the reinforcement of the wiring board 201 having a low flexural rigidity, the stress acting on bonding members 24a positioned at outer peripheral corner portions of the plurality of bonding members 24a can be distributed to bonding members 24a positioned at the center portion of the plurality of bonding members 24a or to the plurality of bonding members 14, thus concentration of the stress on the bonding members 24a positioned at the outer peripheral corner portions can be suppressed, and the reliability of the bonding is improved.

Here, description will be given focusing on one pad 13 and one bonding member 14. Although it is preferable that the entirety of the surface of the pad 13 exposed through the opening portion of the unillustrated solder resist is in contact with the bonding member 14, the entirety of the surface of the pad 13 is not necessarily in contact with the bonding member 14, and part of the surface of the pad 13 can be not in contact with the bonding member 14. The same applies to the pad 23 and the bonding member 24.

To be noted, in the case where the entirety of the surface of each of the plurality of pads 13 is in contact with the corresponding one of the plurality of bonding members 14, the total area S1 is equal to the sum of the surface area of the plurality of pads 13. The same applies to the total area S2.

In the plurality of pads 51 of the wiring member 11, the total area (bonding area) of a portion that comes into contact with the plurality of bonding members 14 will be denoted by S3. In addition, in the plurality of pads 52 of the wiring member 11, the total area (bonding area) of a portion that comes into contact with the plurality of bonding members 24 will be denoted by S4. The total area S3 is an example of a third total area, and the total area S4 is an example of a fourth total area. In the first embodiment, S3<S4 holds, that is, the total area S4 is larger than the total area S3.

As a result of the relationship of S3<S4, the wiring board 201 having a relatively low flexural rigidity as compared with the wiring board 101 is reinforced by the plurality of bonding members 24 having a larger bonding area than the plurality of bonding members 14, and thus warpage of the wiring board 201 in the thermal fatigue test is reduced. Since the warpage of the wiring board 201 is reduced, the stress acting on the plurality of bonding members 24a is reduced. In addition, as a result of the reinforcement of the wiring board 201 having a low flexural rigidity, the stress acting on bonding members 24a positioned at outer peripheral corner portions of the plurality of bonding members 24a can be distributed to bonding members 24a positioned at the center portion of the plurality of bonding members 24a or to the plurality of bonding members 14, thus concentration of the stress on the bonding members 24a positioned at the outer peripheral corner portions can be suppressed, and the reliability of the bonding is improved.

Here, description will be given focusing on one pad 51 and one bonding member 14. Although it is preferable that the entirety of the surface of the pad 51 exposed through the opening portion of the unillustrated solder resist is in contact with the bonding member 14, the entirety of the surface of the pad 51 is not necessarily in contact with the bonding member 14, and part of the surface of the pad 51 can be not in contact with the bonding member 14. The same applies to the pad 52 and the bonding member 24.

To be noted, in the case where the entirety of the surface of each of the plurality of pads 51 is in contact with the corresponding one of the plurality of bonding members 14, the total area S3 is equal to the sum of the surface area of the plurality of pads 51. The same applies to the total area S4.

In addition, the area S22 of each of the two pads 23b illustrated in FIG. 5A is preferably larger than the area S21 of one pad 23a different from the two pads 23b among the plurality of pads 23. As a result of this, the wiring board 201 is strongly reinforced by the bonding members 24b illustrated in FIG. 4A, and thus the reliability of the bonding is further improved.

In addition, the area S22 of each of the two pads 23b illustrated in FIG. 5A is preferably larger than the area S11 of one of the plurality of pads 13 illustrated in FIG. 5D. As a result of this, the wiring board 201 is strongly reinforced by the bonding members 24b illustrated in FIG. 4A, and thus the reliability of the bonding is further improved.

As viewed in the Z direction, each pad 13 has a circular shape. As viewed in the Z direction, each pad 23a has a circular shape. The area S21 of each pad 23a is equal to the area S11 of each pad 13. That is, each pad 23a has the same size as each pad 13. In addition, as viewed in the Z direction, each pad 23b has a rectangular shape.

In addition, the area S42 of each of the two pads 52b illustrated in FIG. 5B is preferably larger than the area S41 of one pad 52a different from the two pads 52b among the plurality of pads 52. As a result of this, the wiring board 201 is strongly reinforced by the bonding members 24b illustrated in FIG. 4A, and thus the reliability of the bonding is further improved.

In addition, the area S42 of each of the two pads 52b illustrated in FIG. 5B is preferably larger than the area S31 of one of the plurality of pads 51 illustrated in FIG. 5C. As a result of this, the wiring board 201 is strongly reinforced by the bonding members 24b illustrated in FIG. 4A, and thus the reliability of the bonding is further improved.

As viewed in the Z direction, each pad 51 has a circular shape. As viewed in the Z direction, each pad 52a has a circular shape. The area S41 of each pad 52a is equal to the area S31 of each pad 51. That is, each pad 52a has the same size as each pad 51. In addition, as viewed in the Z direction, each pad 52b has a rectangular shape.

In addition, the area S21 of each pad 23a is equal to the area S41 of each pad 52a. In addition, the area S11 of each pad 13 is equal to the area S31 of each pad 51.

The flexural rigidity of the wiring board 101 and the flexural rigidity of the wiring board 201 may be obtained by measurement, but can be also obtained by calculation. The wiring boards 101 and 201 each have a Young's modulus of, for example, several tens [Gpa]. The length of the wiring board 101 in the X direction will be denoted by W1, and the length of the wiring board 201 in the X direction will be denoted by W2. In the first embodiment, W1>W2 holds. That is, the length W2 of the wiring board 201 in the X direction is smaller than the length W1 of the wiring board 101 in the X direction. In addition, the thickness of the wiring board 101 in the Z direction will be denoted by H1, and the thickness of the wiring board 201 in the Z direction will be denoted by H2. In the first embodiment, H1>H2 holds. That is, the thickness H2 of the wiring board 201 in the Z direction is smaller than the thickness H1 of the wiring board 101 in the Z direction.

In addition, the Young's modulus of the wiring board 101 will be denoted by E1, the Young's modulus of the wiring board 201 will be denoted by E2, the flexural rigidity of the wiring board 101 will be denoted by K1, and the flexural rigidity of the wiring board 201 will be denoted by K2. The flexural rigidity K1 is expressed by E₁×W₁×H₁³/12, and the flexural rigidity K2 is expressed by E₂×W₂×H₂³/12. To be noted, E₁ and E₂ in the formula are the same as the Young's moduli E1 and E2, W₁ and W₂ are the same as the lengths W1 and W2, and H₁ and H₂ are the same as the thicknesses H1 and H2. As described above, the flexural rigidity K1 of the wiring board 101 can be obtained by E₁×W₁×H₁³/12, and the flexural rigidity K2 of the wiring board 201 can be obtained by E₂×W₂×H₂³/12.

In the case where the wiring boards 101 and 201 each include a plurality of wiring layers constituted by FR4 formed from glass epoxy and wiring formed from copper (Cu), the Young's modulus E1 of the wiring board 101 and the Young's modulus E2 of the wiring board 201 can be approximately equal. The magnitude relationship between the flexural rigidity K1 of the wiring board 101 and the flexural rigidity K2 of the wiring board 201 can be K1>K2. As described above, the flexural rigidity K1 of the wiring board 101 and the flexural rigidity K2 of the wiring board 201 can be obtained by using the formula described above, and the magnitude relationship between the flexural rigidity K1 and the flexural rigidity K2 can be obtained by comparing the obtained flexural rigidities K1 and K2. K1>K2 being satisfied means that E₁×W₁×H₁³/12>E₂×W₂×H₂³/12 and E₁×W₁×H₁³>E₂×W₂×H₂³ are satisfied.

The projected area of each of the electronic components 102a and 102b in the case of projecting the electronic components 102a and 102b onto a virtual X-Y plane in plan view of the processing module 500, that is, when the processing module 500 is viewed in the Z direction, is larger than the projected area of the wiring member 11 in the case of projecting the wiring member 11 onto the virtual X-Y plane. Further, as illustrated in FIG. 3, part of the electronic component 102a overlaps with part of the wiring member 11 in the Z direction. In addition, part of the electronic component 102b overlaps with part of the wiring member 11 in the Z direction.

In addition, as illustrated in FIGS. 3 and 4B, the electronic component 102a includes side surfaces 1021a and 1022a apart from each other in the Y direction. The side surface 1021a is an example of a first side surface, and the side surface 1022a is an example of a second side surface. The wiring member 11 is disposed between a virtual plane V1 including the side surface 1021a and a virtual plane V2 including the side surface 1022a. The virtual plane V1 is an example of a first virtual plane, and the virtual plane V2 is an example of a second virtual plane.

As described above, the electronic components 102a and 102b are disposed across the wiring member 11 on the wiring board 201 having a relatively low flexural rigidity. Therefore, the wiring board 201 is more likely to be deformed due to the difference in the linear expansion coefficient between the wiring board 201 and the electronic components 102a and 102b and thermal deformation of the electronic components 102a and 102b but according to the first embodiment, the deformation (warpage) of the wiring board 201 is more effectively suppressed by the bonding members 24b bonded to the pads 23b and pads 52b, and thus the reliability of the bonding is further improved.

To be noted, the shape and size of each of the pads 13, 23a, 23b, 51, 52a, and 52b are not limited to the example described above. For example, although the shape and size of the pad 23a are the same as the shape and size of the pad 13 in the first embodiment, these may be different. In addition, although the shape and size of the pad 23a are the same as the shape and size of the pad 52a in the first embodiment, these may be different. In addition, although the shape and size of the pad 52a are the same as the shape and size of the pad 51 in the first embodiment, these may be different. In addition, although the shape and size of the pad 13 are the same as the shape and size of the pad 51 in the first embodiment, these may be different. In addition, although the shape and size of the pad 23b are the same as the shape and size of the pad 52b in the first embodiment, these may be different.

In addition, although a group of the pad 51, the through hole conductor 12, and the pad 52a that are electrically connected to each other in the wiring member 11 can be used for a signal line, a power supply line, or a grounding line, the pad 52b can be a dummy pad that is not used for any of the signal line, the power supply line, and the grounding line.

### First Modification Example of First Embodiment

A first modification example of the first embodiment will be described. Although a case where the pad 23b has a rectangular shape as illustrated in FIG. 5A and the pad 52b has a rectangular shape as illustrated in FIG. 5B has been described as an example in the first embodiment, the configuration is not limited to this.

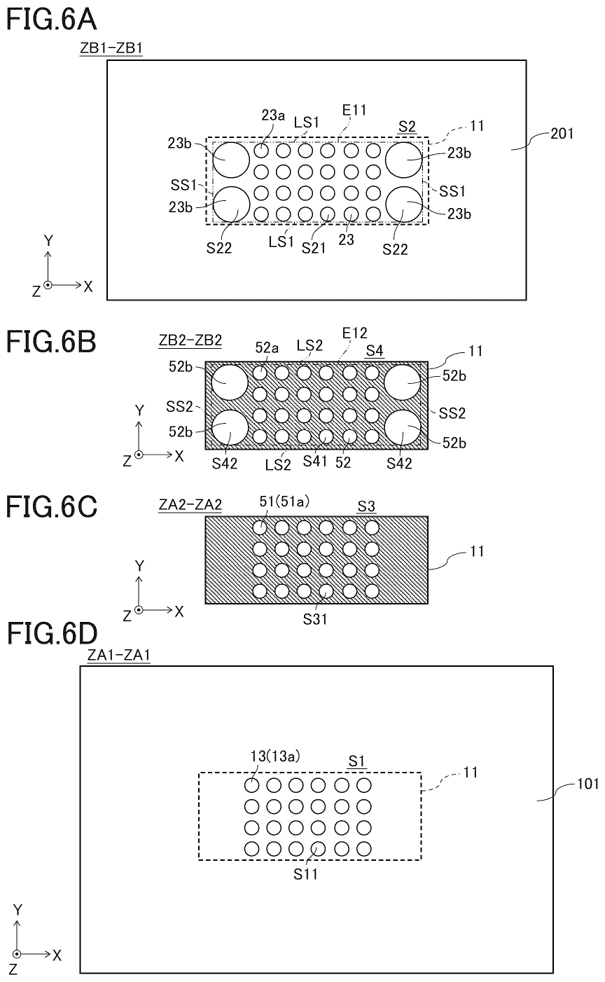

FIG. 6A is a section view of the wiring board 201 according to the first modification example of the first embodiment. FIG. 6B is a section view of the wiring member 11 according to the first modification example of the first embodiment. FIG. 6C is a section view of the wiring member 11 according to the first modification example of the first embodiment. FIG. 6D is a section view of the wiring board 101 according to the first modification example of the first embodiment. FIG. 6A schematically illustrates the wiring board 201 in a case where a cross-section of the wiring board 201 taken along a virtual plane ZB1-ZB1 illustrated in FIG. 4A is viewed in the −Z direction. FIG. 6B schematically illustrates the wiring member 11 in a case where a cross-section of the wiring member 11 taken along a virtual plane ZB2-ZB2 illustrated in FIG. 4A is viewed in the −Z direction. FIG. 6C schematically illustrates the wiring member 11 in a case where a cross-section of the wiring member 11 taken along a virtual plane ZA2-ZA2 illustrated in FIG. 4A is viewed in the −Z direction. FIG. 6D schematically illustrates the wiring board 101 in a case where a cross-section of the wiring board 101 taken along a virtual plane ZA1-ZA1 illustrated in FIG. 4A is viewed in the −Z direction.

The number of the plurality of pads 23 of the wiring board 201 illustrated in FIG. 6A is larger than the number of the plurality of pads 13 of the wiring board 101 illustrated in FIG. 6D. In addition, the number of the plurality of pads 52 of the wiring member 11 illustrated in FIG. 6B is larger than the number of the plurality of pads 51 of the wiring member 11 illustrated in FIG. 6C. Further, similarly to the first embodiment, the total area S2 is larger than the total area S1, and the total area S4 is larger than the total area S3. Further, similarly to the first embodiment, the reliability of the bonding is improved.

As illustrated in FIG. 6A, the plurality of pads 23 of the wiring board 201 include two or more (four in the first modification example of the first embodiment) pads 23b that do not overlap with any of the plurality of pads 13 of the wiring board 101 in the Z direction. The plurality of pads other than the four pads 23b among the plurality of pads 23 are pads 23a.

Similarly to the first embodiment, the shape and size of the pad 23a are the same as the shape and size of the pad 13. In addition, similarly to the first embodiment, the shape and size of the pad 52a are the same as the shape and size of the pad 51. In addition, similarly to the first embodiment, the shape and size of the pad 23a are the same as the shape and size of the pad 52a, and the shape and size of the pad 13 are the same as the shape and size of the pad 51.

As illustrated in FIG. 6A, the four pads 23b are each in contact with at least one (one in the first modification example of the first embodiment) of the two long sides LS1 of the region E11. In addition, the four pads 23b are each in contact with one of the two short sides SS1 of the region E11. Further, two of the four pads 23b are disposed on each side of the plurality of pads 23a in the X direction.

As illustrated in FIG. 6B, the plurality of pads 52 of the wiring member 11 include two or more (four in the first modification example of the first embodiment) pads 52b that do not overlap with any of the plurality of pads 51 of the wiring member 11 in the Z direction. The plurality of pads other than the four pads 52b among the plurality of pads 52 are pads 52a. The plurality of pads 52a each overlap with corresponding one of the plurality of pads 51 in the Z direction.

As illustrated in FIG. 6B, the four pads 52b are each in contact with at least one (one in the first modification example of the first embodiment) of the two long sides LS2 of the region E12. In addition, the two pads 52b are each in contact with one of the two short sides SS2 of the region E12. Further, two of the four pads 52b are disposed on each side of the plurality of pads 52a in the X direction.

As viewed in the Z direction, the pads 23b illustrated in FIG. 6A each have a circular shape. The area S22 of each of the four pads 23b is preferably larger than the area S21 of one pad 23a other than the four pads 23b among the plurality of pads 23. As a result of this, the wiring board 201 is strongly reinforced by the bonding members 24b illustrated in FIG. 4A, and thus the reliability of the bonding is further improved.

In addition, the area S22 of each of the four pads 23b illustrated in FIG. 6A is preferably larger than the area S11 of one of the plurality of pads 13 illustrated in FIG. 6D. As a result of this, the wiring board 201 is strongly reinforced by the bonding members 24b illustrated in FIG. 4A, and thus the reliability of the bonding is further improved.

In addition, as viewed in the Z direction, the pads 52b illustrated in FIG. 6B each have a circular shape. The area S42 of each of the four pads 52b is preferably larger than the area S41 of one pad 52a other than the four pads 52b among the plurality of pads 52. As a result of this, the wiring board 201 is strongly reinforced by the bonding members 24b illustrated in FIG. 4A, and thus the reliability of the bonding is further improved.

In addition, the area S42 of each of the four pads 52b illustrated in FIG. 6B is preferably larger than the area S31 of one of the plurality of pads 51 illustrated in FIG. 6C. As a result of this, the wiring board 201 is strongly reinforced by the bonding members 24b illustrated in FIG. 4A, and thus the reliability of the bonding is further improved.

To be noted, the size of the pad 23b is preferably larger than the size of the pad 23a, but these sizes may be the same. Similarly, the size of the pad 52b is preferably larger than the size of the pad 52a, but these sizes may be the same.

In addition, the shape of the pad 23b and the shape of the pad 52b are the same, but may be different. In addition, the size of the pad 23b and the size of the pad 52b are the same, but may be different.

### Second Modification Example of First Embodiment

A second modification example of the first embodiment will be described. A case where the pad 23b has a circular shape and a larger size than the pad 23a as illustrated in FIG. 6A has been described in the first modification example of the first embodiment described above. In addition, a case where the pad 52b has a circular shape and a larger size than the pad 52a as illustrated in FIG. 6B has been described in the first modification example of the first embodiment described above.

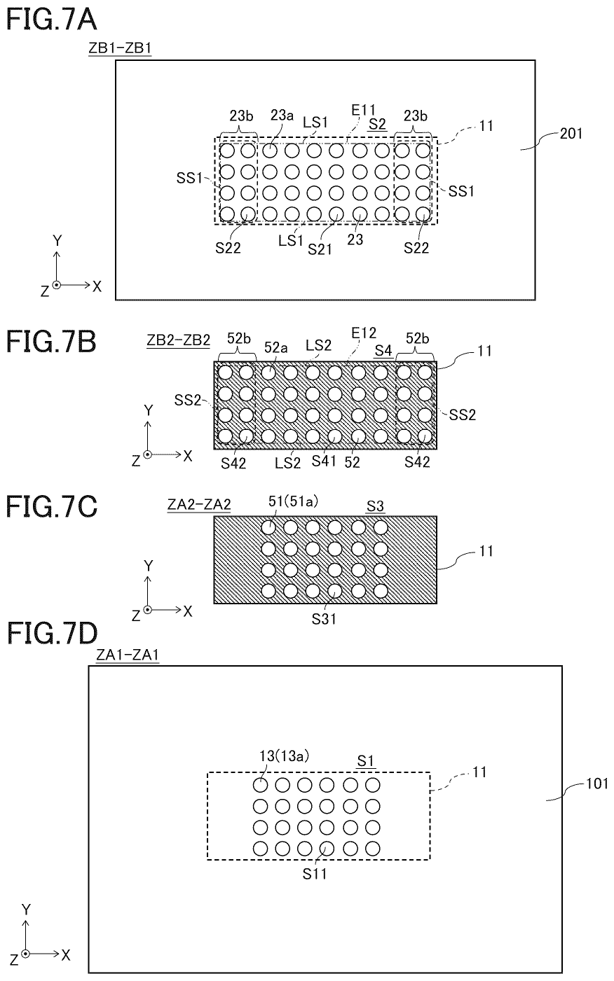

FIG. 7A is a section view of the wiring board 201 according to the second modification example of the first embodiment. FIG. 7B is a section view of the wiring member 11 according to the second modification example of the first embodiment. FIG. 7C is a section view of the wiring member 11 according to the second modification example of the first embodiment. FIG. 7D is a section view of the wiring board 101 according to the second modification example of the first embodiment. FIG. 7A schematically illustrates the wiring board 201 in a case where a cross-section of the wiring board 201 taken along a virtual plane ZB1-ZB1 illustrated in FIG. 4A is viewed in the −Z direction. FIG. 7B schematically illustrates the wiring member 11 in a case where a cross-section of the wiring member 11 taken along a virtual plane ZB2-ZB2 illustrated in FIG. 4A is viewed in the −Z direction. FIG. 7C schematically illustrates the wiring member 11 in a case where a cross-section of the wiring member 11 taken along a virtual plane ZA2-ZA2 illustrated in FIG. 4A is viewed in the −Z direction. FIG. 7D schematically illustrates the wiring board 101 in a case where a cross-section of the wiring board 101 taken along a virtual plane ZA1-ZA1 illustrated in FIG. 4A is viewed in the −Z direction.

The number of the plurality of pads 23 of the wiring board 201 illustrated in FIG. 7A is larger than the number of the plurality of pads 13 of the wiring board 101 illustrated in FIG. 7D. In addition, the number of the plurality of pads 52 of the wiring member 11 illustrated in FIG. 7B is larger than the number of the plurality of pads 51 of the wiring member 11 illustrated in FIG. 7C. Further, similarly to the first embodiment, the total area S2 is larger than the total area S1, and the total area S4 is larger than the total area S3. Further, similarly to the first embodiment, the reliability of the bonding is improved.

As illustrated in FIG. 7A, the plurality of pads 23 of the wiring board 201 include two or more (sixteen in the second modification example of the first embodiment) pads 23b that do not overlap with any of the plurality of pads 13 of the wiring board 101 in the Z direction. The plurality of pads other than the sixteen pads 23b among the plurality of pads 23 are pads 23a.

Similarly to the first embodiment, the shape and size of the pad 23a are the same as the shape and size of the pad 13. In addition, similarly to the first embodiment, the shape and size of the pad 52a are the same as the shape and size of the pad 51. In addition, similarly to the first embodiment, the shape and size of the pad 23a are the same as the shape and size of the pad 52a, and the shape and size of the pad 13 are the same as the shape and size of the pad 51.

In the second modification example of the first embodiment, the shape and size of the pad 23b are the same as the shape and size of the pad 23a. In addition, in the second modification example of the first embodiment, the shape and size of the pad 52b are the same as the shape and size of the pad 52a. The reliability of the bonding is also improved in such a case.

### Third Modification Example of First Embodiment

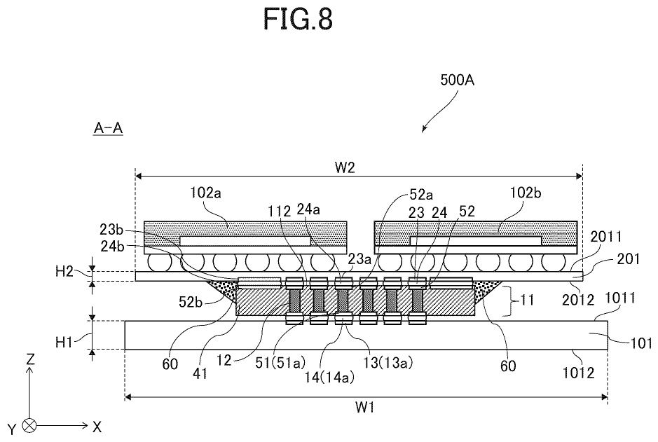

A third modification example of the first embodiment will be described. FIG. 8 is a section view of a processing module 500A according to the third modification example of the first embodiment. In FIG. 8, the processing module 500 illustrated in FIG. 3 is replaced by the processing module 500A, and the processing module 500A in a case where a cross-section of the processing module 500A taken along a virtual plane A-A is viewed in the +Y direction is schematically illustrated. The virtual plane A-A is a virtual plane parallel to the X-Z plane.

The processing module 500A of the third modification example has a configuration in which a resin member 60 is added to the processing module 500. The resin member 60 is a resin member for reinforcement, and bonds the wiring member 11 to the wiring board 201. Specifically, the resin member 60 is disposed at an outer periphery of the wiring member 11, and is in contact with side surfaces of the wiring member 11 and the main surface 2012 of the wiring board 201. The resin member 60 is also in contact with the bonding members 24b.

As described above, the wiring board 201 is reinforced by the resin member 60, thus the warpage of the wiring board 201 is reduced, and the reliability of bonding in the processing module 500A is improved.

### Second Embodiment

A second embodiment will be described. In the description below, it is assumed that elements denoted by the same reference signs as in the first embodiment have substantially the same configuration as those described in the first embodiment unless described otherwise, and part different from the first embodiment will be mainly described.

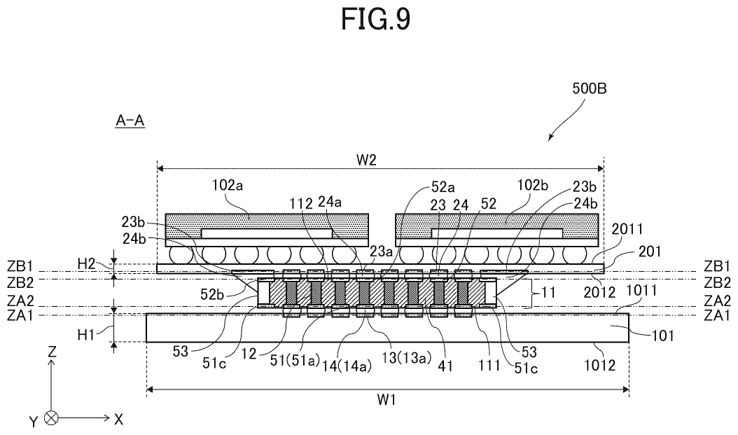

FIG. 9 is a section view of a processing module 500B according to the second embodiment. In FIG. 9, the processing module 500 illustrated in FIG. 3 is replaced by the processing module 500B, and the processing module 500B in a case where a cross-section of the processing module 500B taken along the virtual plane A-A is viewed in the +Y direction is schematically illustrated. The virtual plane A-A is a virtual plane parallel to the X-Z plane.

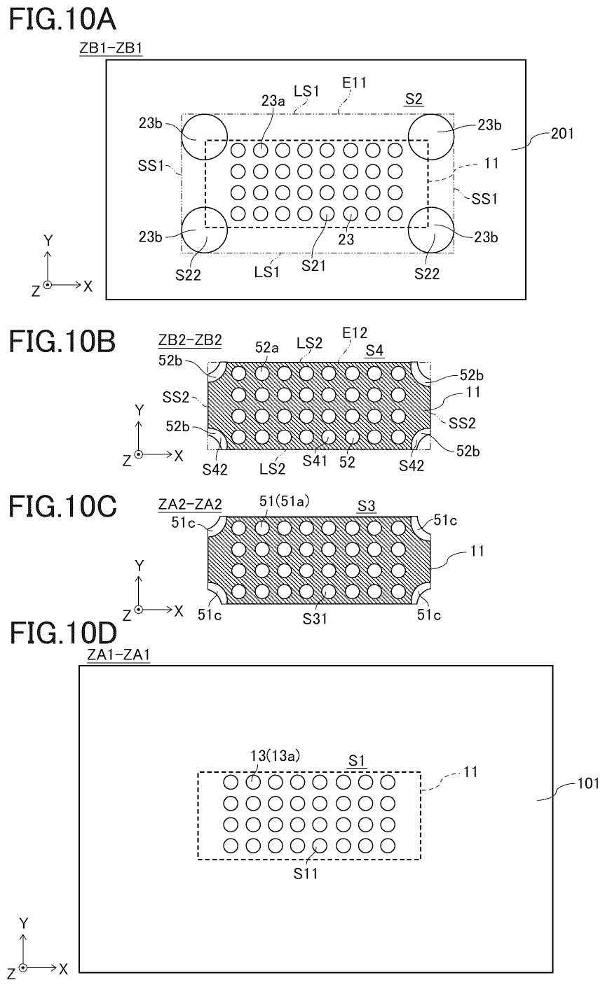

FIG. 10A is a section view of the wiring board 201 according to the second embodiment. FIG. 10B is a section view of the wiring member 11 according to the second embodiment. FIG. 10C is a section view of the wiring member 11 according to the second embodiment. FIG. 10D is a section view of the wiring board 101 according to the second embodiment. FIG. 10A schematically illustrates the wiring board 201 in a case where a cross-section of the wiring board 201 taken along a virtual plane ZB1-ZB1 illustrated in FIG. 9 is viewed in the −Z direction. FIG. 10B schematically illustrates the wiring member 11 in a case where a cross-section of the wiring member 11 taken along a virtual plane ZB2-ZB2 illustrated in FIG. 9 is viewed in the −Z direction. FIG. 10C schematically illustrates the wiring member 11 in a case where a cross-section of the wiring member 11 taken along a virtual plane ZA2-ZA2 illustrated in FIG. 9 is viewed in the −Z direction. FIG. 10D schematically illustrates the wiring board 101 in a case where a cross-section of the wiring board 101 taken along a virtual plane ZA1-ZA1 illustrated in FIG. 9 is viewed in the −Z direction.

The wiring member 11 includes a plurality of pads 51 disposed on the main surface 111 and two or more pads disposed on the main surface 111. In the second embodiment, the two or more pads disposed on the main surface 111 are four pads 51c. The four pads 51c are pads not used for bonding with the wiring board 101. That is, the four pads 51c are not bonded to the wiring board 101. In addition, the wiring member 11 includes a plurality of pads 52 disposed on the main surface 112.

The magnitude relationship between the number of the plurality of pads 13 of the wiring board 101, the number of the plurality of pads 51 of the wiring member 11, the number of the plurality of pads 23 of the wiring board 201, and the number of the plurality of pads 52 of the wiring member 11 in the second embodiment is as described in the first embodiment.

That is, in the second embodiment, the number of the plurality of pads 23 of the wiring board 201 is larger than the number of the plurality of pads 13 of the wiring board 101. In the example of FIGS. 10A and 10D, the number of the plurality of pads 23 is thirty-six, and the number of the plurality of pads 13 is thirty-two. In addition, the number of the plurality of pads 52 of the wiring member 11 is larger than the number of the plurality of pads 51 of the wiring member 11. In the example of FIGS. 10B and 10C, the number of the plurality of pads 52 is thirty-six, and the number of the plurality of pads 51 is thirty-two. Further, the number of the plurality of bonding members 24 is larger than the number of the plurality of bonding members 14. To be noted, the number of the pads 51c not used for bonding is four.

The plurality of pads 23 of the wiring board 201 include two or more (four in the second embodiment) pads 23b that do not overlap with any of the plurality of pads 13 of the wiring board 101 in the Z direction. Among the plurality of pads 23, a plurality of pads other than the four pads 23b will be referred to as pads 23a. In the example of FIG. 10A, thirty-two (8×4) pads 23a are provided.

Here, as illustrated in FIG. 10A, a rectangular region E11 of the smallest area enclosing the plurality of pads 23 is defined. The region E11 is an example of a first smallest rectangular region. The outer periphery of the region E11 includes two long sides LS1 extending in the X direction and apart from each other in the Y direction, and two short sides SS1 extending in the Y direction and apart from each other in the X direction.

The four pads 23b are each in contact with at least one (one in the second embodiment) of the two long sides LS1 of the region E11. In addition, the four pads 23b are each in contact with one of the two short sides SS1 of the region E11. Further, two of the four pads 23b are disposed at each far end in the plurality of pads 23a in the X direction.

The plurality of pads 52 of the wiring member 11 include two or more (four in the second embodiment) pads 52b that do not overlap with any of the plurality of pads 51 of the wiring member 11 in the Z direction. Among the plurality of pads 52, a plurality of pads other than the four pads 52b will be referred to as pads 52a. In the example of FIG. 10B, thirty-two (8×4) pads 52a are provided.

The plurality of pads 13 each overlap with corresponding one of the plurality of pads 51 in the Z direction. The plurality of pads 51 each overlap with corresponding one of the plurality of pads 52a in the Z direction. The plurality of pads 52a each overlap with corresponding one of the plurality of pads 23a in the Z direction. In addition, the four pads 52b each overlap with corresponding one of the four pads 23b in the Z direction. In addition, the four pads 51c each overlap with corresponding one of the four pads 52b in the Z direction.

Here, as illustrated in FIG. 10B, a rectangular region E12 of the smallest area enclosing the plurality of pads 52 is defined. The region E12 is an example of a second smallest rectangular region. The outer periphery of the region E12 includes two long sides LS2 extending in the X direction and apart from each other in the Y direction, and two short sides SS2 extending in the Y direction and apart from each other in the X direction.

The four pads 52b are each in contact with at least one (one in the second embodiment) of the two long sides LS2 of the region E12. In addition, the four pads 52b are each in contact with one of the two short sides SS2 of the region E12. Further, two of the four pads 52b are disposed at each far end in the plurality of pads 52a in the X direction.

The plurality of bonding members 24 include four bonding members 24b respectively corresponding to the four pads 23b. In addition, the plurality of bonding members 24 include a plurality of bonding members 24a respectively corresponding to the plurality of pads 23a.

That is, each of the four pads 23b is bonded to corresponding one of the four pads 52b via corresponding one of the four bonding members 24b. In addition, each of the plurality of pads 23a is bonded to corresponding one of the plurality of pads 52a via corresponding one of the plurality of bonding members 24a. To be noted, each of the plurality of pads 13 is bonded to corresponding one of the plurality of pads 51 via corresponding one of the plurality of bonding members 14.

In the second embodiment, similarly to the first embodiment, S1<S2 holds. That is, the total area S2 is larger than the total area S1. In addition, in the second embodiment, similarly to the first embodiment, S3<S4 holds. That is, the total area S4 is larger than the total area S3. Therefore, the reliability of the bonding is improved. To be noted, the magnitude relationship between the area S21 of the pad 23a, the area S22 of the pad 23b, the area S41 of the pad 52a, the area S42 of the pad 52b, the area S31 of the pad 51, and the area S11 of the pad 13 is as described in the first embodiment.

The insulator 41 of the wiring member 11 has end surface through holes formed in end surfaces (side surfaces) thereof. The end surface through hole is formed in at least one side surface of the insulator 41, and is a groove connected to the main surfaces 111 and 112. In the second embodiment, the end surface through hole is a groove formed at a position corresponding to a corner portion between two side surfaces of the insulator 41 and extending from the main surface 111 to the main surface 112 in the Z direction. That is, in the second embodiment, the end surface through holes (grooves) each have a shape obtained by dividing a cylindrical hole into four sectors in plan view.

The wiring member 11 includes conductor patterns 53 disposed in the end surface through holes. the conductor pattern 53 is connected to the pad 52b and the pad 51c. In the second embodiment, the conductor pattern 53 is integrated with the pad 52b and the pad 51c. To be noted, the end surface through holes may be formed in one side surface of the insulator 41. That is, the end surface through holes (grooves) may each have a shape obtained by dividing a cylindrical hole into two semicircles in plan view.

The pads 52b are each positioned at an end portion of the main surface 112 in one of the X direction and the Y direction. The pad 52b is an example of a first end pad. The pads 51c are each positioned at an end portion of the main surface 111 in one of the X direction and the Y direction. The pad 51c is an example of a second end pad.

In the second embodiment, the pads 52b are positioned at corner portions of the main surface 112. That is, the pads 52b are positioned at end portions of the main surface 112 in the X direction and the Y direction. In addition, in the second embodiment, the pads 51c are positioned at corner portions of the main surface 111. That is, the pads 51c are positioned at end portions of the main surface 111 in the X direction and the Y direction.

To form the end surface through hole, first, a sheet substrate (not illustrate) having a sheet shape that is to be divided into the plurality of wiring members 11 is prepared. In the sheet substrate, through holes and through hole conductors are provided at positions corresponding to outer corner portions of the wiring members 11 in the sheet substrate, and the portions corresponding thereto are cut by a cutting apparatus such as a dicer. Thus, the end surface through hole and the conductor pattern 53 are formed at each of the four corners of the wiring member 11 as viewed in the Z direction.

Among the plurality of bonding members 24, the bonding members 24b in contact with the pads 52b are in contact with the conductor patterns 53. That is, the bonding members 24b cover at least part of the conductor patterns 53 positioned at side surfaces of the wiring member 11. The bonding members 24b preferably cover ½ or more of the area of the conductor patterns 53.

Since the conductor patterns 53 in the end surface through holes used for reinforcement can be manufactured in the same process as the through hole conductors 12 used as the signal line, power supply line, or grounding line, no additional processing step needs to be provided, and thus the production cost can be reduced.

As described above, since the conductor patterns 53 are formed in the side surfaces (end surfaces) of the insulator 41, the bonding members 24b can be bonded to not only the pads 52b disposed on the main surface 112 but also the conductor patterns 53 disposed on the side surfaces. As a result of this, warpage of the wiring board 201 caused by thermal deformation can be further reduced, and thus the reliability of the bonding is improved.

To be noted, the formation method for the conductor patterns 53 is not limited to the example described above, and the conductor patterns 53 may be formed by, for example, plating the side surfaces (end surfaces) of the insulator 41 of the wiring member 11 with metal.

### Third Embodiment

A third embodiment will be described. In the description below, it is assumed that elements denoted by the same reference signs as in the first or second embodiment have substantially the same configuration as those described in the first or second embodiment unless described otherwise, and part different from the first and second embodiments will be mainly described.

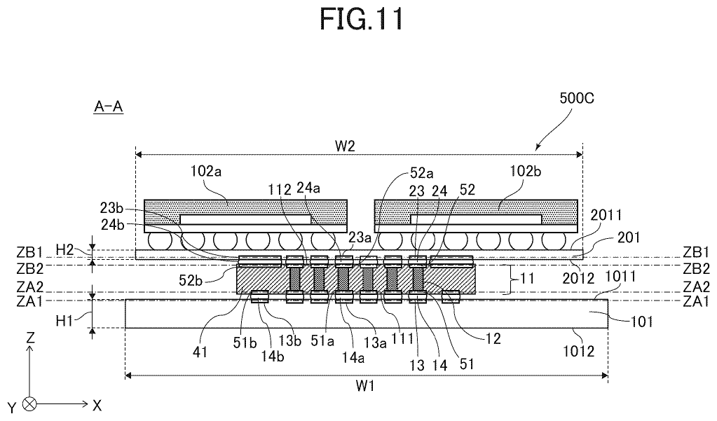

FIG. 11 is a section view of a processing module 500C according to the third embodiment. In FIG. 11, the processing module 500 illustrated in FIG. 3 is replaced by the processing module 500C, and the processing module 500C in a case where a cross-section of the processing module 500C taken along the virtual plane A-A is viewed in the +Y direction is schematically illustrated. The virtual plane A-A is a virtual plane parallel to the X-Z plane.

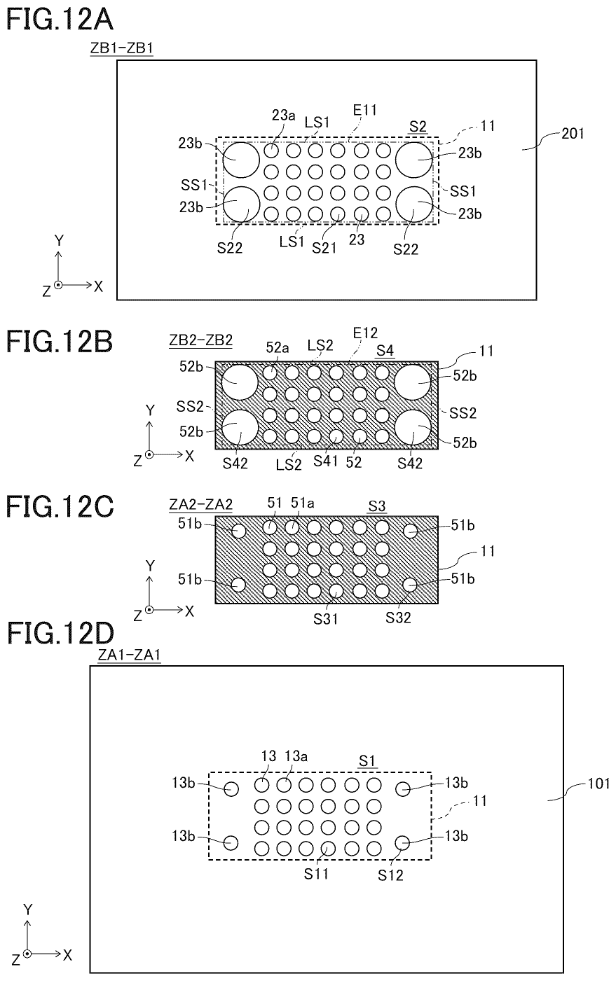

FIG. 12A is a section view of the wiring board 201 according to the third embodiment. FIG. 12B is a section view of the wiring member 11 according to the third embodiment. FIG. 12C is a section view of the wiring member 11 according to the third embodiment. FIG. 12D is a section view of the wiring board 101 according to the third embodiment. FIG. 12A schematically illustrates the wiring board 201 in a case where a cross-section of the wiring board 201 taken along a virtual plane ZB1-ZB1 illustrated in FIG. 11 is viewed in the −Z direction. FIG. 12B schematically illustrates the wiring member 11 in a case where a cross-section of the wiring member 11 taken along a virtual plane ZB2-ZB2 illustrated in FIG. 11 is viewed in the −Z direction. FIG. 12C schematically illustrates the wiring member 11 in a case where a cross-section of the wiring member 11 taken along a virtual plane ZA2-ZA2 illustrated in FIG. 11 is viewed in the −Z direction. FIG. 12D schematically illustrates the wiring board 101 in a case where a cross-section of the wiring board 101 taken along a virtual plane ZA1-ZA1 illustrated in FIG. 11 is viewed in the −Z direction.

Regarding the processing module 500 of the first embodiment described above, a case where all of the plurality of pads 13 are pads 13a used as a signal line, power supply line, or grounding line, all of the plurality of pads 51 are pads 51a used as a signal line, power supply line, or grounding line, and all of the plurality of bonding members 14 are pads 14a used as a signal line, power supply line, or grounding line has been described.

In the module 500C of the third embodiment, two or more of the plurality of pads 13, for example, four pads 13b are pads other than the pads 13a. In addition, in the module 500C of the third embodiment, two or more of the plurality of pads 51, for example, four pads 51b are pads other than the pads 51a. In addition, in the module 500C of the third embodiment, two or more of the plurality of bonding members 14, for example, four bonding members 14b are bonding members other than the bonding members 14a.

To be noted, in the module 500C of the third embodiment, two or more of the plurality of pads 23, for example, four pads 23b are pads other than the pads 23a. In addition, in the module 500C of the third embodiment, two or more of the plurality of pads 52, for example, four pads 52b are pads other than the pads 52a. In addition, in the module 500C of the third embodiment, two or more of the plurality of bonding members 24, for example, four bonding members 24b are bonding members other than the bonding members 24a.

The four pads 13b and the four pads 51b are bonded to each other via the four bonding members 14b. The four pads 23b and the four pads 52b are bonded to each other via the four bonding members 24b.

The four pads 13b of the wiring board 101, the four bonding members 14b, the four pads 51b of the wiring member 11, and the four pads 52b of the wiring board 201, are not used for any of a signal line, a power supply line, and a grounding line. That is, the pads 13b and the pads 52b are not interconnected by the through hole conductors. In the third embodiment, the four pads 13b of the wiring board 101 are bonded to the four pads 51b of the wiring member 11 via the four bonding members 14b.

In the third embodiment, similarly to the first embodiment, S1<S2 holds. That is, the total area S2 is larger than the total area S1. As a result of the relationship of S1<S2, the wiring board 201 having a relatively low flexural rigidity as compared with the wiring board 101 is reinforced by the plurality of bonding members 24 having a larger bonding area than the plurality of bonding members 14, and thus warpage of the wiring board 201 in the thermal fatigue test is reduced.

In addition, by adjusting the area S12 of each pad 13b and the area S22 of each pad 23b such that the size of each pad 13b is smaller than the size of each pad 23b, the total areas S1 and S2 are adjusted. As a result of this, the stress acting on bonding members 24a positioned at outer peripheral corner portions of the plurality of bonding members 24a can be distributed to bonding members 24a positioned at the center portion of the plurality of bonding members 24a or to the plurality of bonding members 14, and thus the reliability of the bonding is improved.

In addition, in the third embodiment, similarly to the first embodiment, S3<S4 holds. That is, the total area S4 is larger than the total area S3. As a result of the relationship of S3<S4, the wiring board 201 having a relatively low flexural rigidity as compared with the wiring board 101 is reinforced by the plurality of bonding members 24 having a larger bonding area than the plurality of bonding members 14, and thus warpage of the wiring board 201 in the thermal fatigue test is reduced.

In addition, by adjusting the area S32 of each pad 52b and the area S42 of each pad 52b such that the size of each pad 51b is smaller than the size of each pad 52b, the total areas S3 and S4 are adjusted. As a result of this, the stress acting on bonding members 24a positioned at outer peripheral corner portions of the plurality of bonding members 24a can be distributed to bonding members 24a positioned at the center portion of the plurality of bonding members 24a or to the plurality of bonding members 14, and thus the reliability of the bonding is improved.

To be noted, one of the four pads 13b of the wiring board 101, the four bonding members 14b, the four pads 51b of the wiring member 11, the four pads 52b of the wiring member 11, the four bonding members 24b, and the four pads 23b of the wiring board 201 may be used for any of a signal line, a power supply line, and a grounding line. For example, a pad 51b and a pad 52b may be interconnected by a through hole conductor, and the group of the pad 51b, the pad 52b, and the through hole conductor may be used for one of a signal line, a power supply line, and a grounding line.

### Fourth Embodiment

A fourth embodiment will be described. In the description below, it is assumed that elements denoted by the same reference signs as in the first to third embodiments have substantially the same configuration as those described in the first to third embodiments unless described otherwise, and part different from the first to third embodiments will be mainly described.

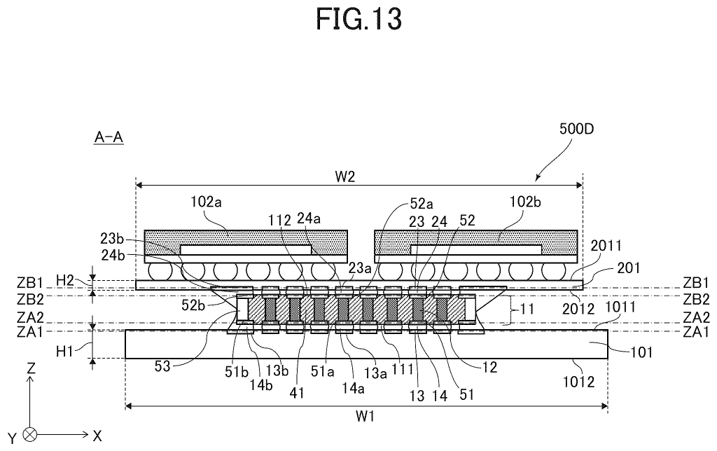

FIG. 13 is a section view of a processing module 500D according to the fourth embodiment. In FIG. 13, the processing module 500 illustrated in FIG. 3 is replaced by the processing module 500D, and the processing module 500D in a case where a cross-section of the processing module 500D taken along the virtual plane A-A is viewed in the +Y direction is schematically illustrated. The virtual plane A-A is a virtual plane parallel to the X-Z plane.

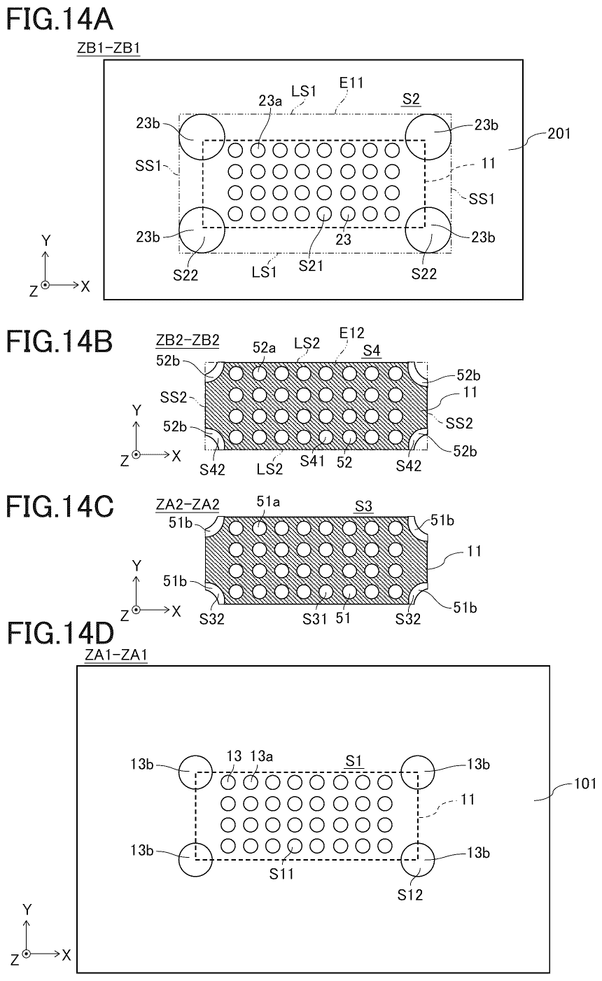

FIG. 14A is a section view of the wiring board 201 according to the fourth embodiment. FIG. 14B is a section view of the wiring member 11 according to the fourth embodiment. FIG. 14C is a section view of the wiring member 11 according to the fourth embodiment. FIG. 14D is a section view of the wiring board 101 according to the fourth embodiment. FIG. 14A schematically illustrates the wiring board 201 in a case where a cross-section of the wiring board 201 taken along a virtual plane ZB1-ZB1 illustrated in FIG. 13 is viewed in the −Z direction. FIG. 14B schematically illustrates the wiring member 11 in a case where a cross-section of the wiring member 11 taken along a virtual plane ZB2-ZB2 illustrated in FIG. 13 is viewed in the −Z direction. FIG. 14C schematically illustrates the wiring member 11 in a case where a cross-section of the wiring member 11 taken along a virtual plane ZA2-ZA2 illustrated in FIG. 13 is viewed in the −Z direction. FIG. 14D schematically illustrates the wiring board 101 in a case where a cross-section of the wiring board 101 taken along a virtual plane ZA1-ZA1 illustrated in FIG. 13 is viewed in the −Z direction.

The plurality of pads 13 of the wiring board 101 of the fourth embodiment include four pads 13b as two or more pads. The plurality of bonding members 14 include four bonding members 14b as two or more bonding members.

The wiring member 11 of the fourth embodiment has a similar configuration to the wiring member 11 of the second embodiment, and includes four pads 51b corresponding to the four pads 51c of the second embodiment. That is, although the four pads 51c of the second embodiment are not bonded to wiring board 101, the four pads 51b of the fourth embodiment are respectively bonded to the four pads 13b of the wiring board 101 via the four bonding members 14b. The four pads 51b are included in the plurality of pads 51.

The magnitude relationship between the number of the plurality of pads 13 of the wiring board 101, the number of the plurality of pads 51 of the wiring member 11, the number of the plurality of pads 23 of the wiring board 201, and the number of the plurality of pads 52 of the wiring member 11 in the fourth embodiment are the same.

In the fourth embodiment, similarly to the first embodiment, S1<S2 holds. That is, the total area S2 is larger than the total area S1. In addition, in the fourth embodiment, similarly to the first embodiment, S3<S4 holds. That is, the total area S4 is larger than the total area S3. Therefore, the reliability of the bonding is improved. To be noted, the area S12 of the pad 13b is larger than the area S11 of the pad 13a. In addition, the area S32 of the pad 51b is larger than the area S31 of the pad 51a.

The insulator 41 of the wiring member 11 has end surface through holes formed in end surfaces (side surfaces) thereof. The end surface through hole is formed in at least one side surface of the insulator 41, and is a groove connected to the main surfaces 111 and 112. In the fourth embodiment, the end surface through hole is a groove formed at a position corresponding to a corner portion between two side surfaces of the insulator 41 and extending from the main surface 111 to the main surface 112 in the Z direction. That is, in the fourth embodiment, the end surface through holes (grooves) each have a shape obtained by dividing a cylindrical hole into four sectors in plan view.

The wiring member 11 includes conductor patterns 53 disposed in the end surface through holes. The conductor pattern 53 is connected to the pad 52b and the pad 51b. In the fourth embodiment, the conductor patterns 53 are integrated with the pads 52b and the pads 51b. To be noted, the end surface through holes may be formed in one side surface of the insulator 41. That is, the end surface through holes (grooves) may each have a shape obtained by dividing a cylindrical hole into two semicircles in plan view.

The pads 52b are positioned at end portions of the main surface 112 in one of the X direction and the Y direction. The pad 52b is an example of a first end pad. The pads 51b are positioned at end portions of the main surface 111 in one of the X direction and the Y direction. The pad 51b is an example of a second end pad.

In the fourth embodiment, the pads 52b are positioned at corner portions of the main surface 112. That is, the pads 52b are positioned at end portions of the main surface 112 in the X direction and the Y direction. In addition, in the fourth embodiment, the pads 51b are positioned at corner portions of the main surface 111. That is, the pads 51b are positioned at end portions of the main surface 111 in the X direction and the Y direction.

Among the plurality of bonding members 14, the bonding members 14b in contact with the pads 51b are in contact with the conductor patterns 53. That is, the bonding members 14b cover at least part of the conductor patterns 53 positioned at the side surfaces of the wiring member 11.

Among the plurality of bonding members 24, the bonding members 24b in contact with the pads 52b are in contact with the conductor patterns 53. That is, the bonding members 24b cover at least part of the conductor patterns 53 positioned at side surfaces of the wiring member 11.

Since the conductor patterns 53 of the end surface through holes used for reinforcement can be manufactured in the same process as the through hole conductors 12 used as the signal line, power supply line, or grounding line, no additional processing step needs to be provided, and thus the production cost can be reduced.

As described above, since the conductor patterns 53 are formed in side surfaces (end surfaces) of the insulator 41, the bonding members 24b can be bonded to not only the pads 52b disposed on the main surface 112 but also the conductor patterns 53 disposed on the side surfaces. As a result of this, warpage of the wiring board 201 caused by thermal deformation can be further reduced, and thus the reliability of the bonding is improved.

In addition, in the fourth embodiment, similarly to the first embodiment, S1<S2 holds. That is, the total area S2 is larger than the total area S1. As a result of the relationship of S1<S2, the wiring board 201 having a relatively low flexural rigidity as compared with the wiring board 101 is reinforced by the plurality of bonding members 24 having a larger bonding area than the plurality of bonding members 14, and thus warpage of the wiring board 201 in the thermal fatigue test is reduced.

In addition, by adjusting the area S12 of each pad 13b and the area S22 of each pad 23b such that the size of each pad 13b is smaller than the size of each pad 23b, the total areas S1 and S2 are adjusted. As a result of this, the stress acting on bonding members 24a positioned at outer peripheral corner portions of the plurality of bonding members 24a can be distributed to bonding members 24a positioned at the center portion of the plurality of bonding members 24a or to the plurality of bonding members 14, and thus the reliability of the bonding is improved.

In addition, in the fourth embodiment, similarly to the first embodiment, S3<S4 holds. That is, the total area S4 is larger than the total area S3. As a result of the relationship of S3<S4, the wiring board 201 having a relatively low flexural rigidity as compared with the wiring board 101 is reinforced by the plurality of bonding members 24 having a larger bonding area than the plurality of bonding members 14, and thus warpage of the wiring board 201 in the thermal fatigue test is reduced.

In addition, by adjusting the area S32 of each pad 51b and the area S42 of each pad 52b such that the size of each pad 51b is smaller than the size of each pad 52b, the total areas S3 and S4 are adjusted. As a result of this, the stress acting on bonding members 24a positioned at outer peripheral corner portions of the plurality of bonding members 24a can be distributed to bonding members 24a positioned at the center portion of the plurality of bonding members 24a or to the plurality of bonding members 14, and thus the reliability of the bonding is improved.

To be noted, the formation method for the conductor patterns 53 is not limited to the example described above, and the conductor patterns 53 may be formed by, for example, plating the side surfaces (end surfaces) of the insulator 41 of the wiring member 11 with metal. In addition, the bonding members 14b may be integrated with the bonding members 24b via the conductor patterns 53.

### Fifth Embodiment

A fifth embodiment will be described. In the description below, it is assumed that elements denoted by the same reference signs as in the first to fourth embodiments have substantially the same configuration as those described in the first to fourth embodiments unless described otherwise, and part different from the first to fourth embodiments will be mainly described.

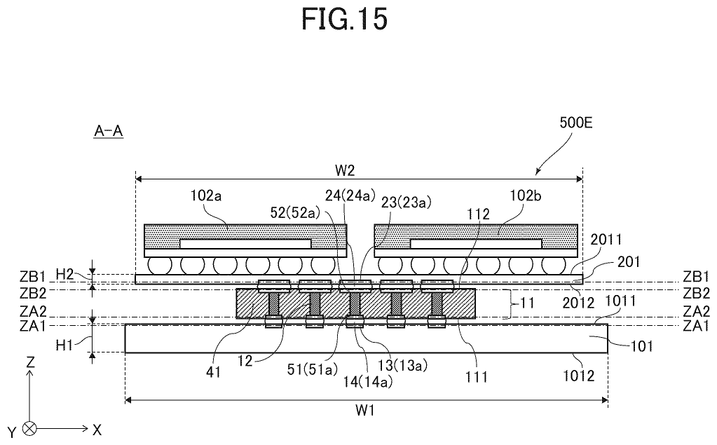

FIG. 15 is a section view of a processing module 500E according to the fifth embodiment. In FIG. 15, the processing module 500 illustrated in FIG. 3 is replaced by the processing module 500E, and the processing module 500E in a case where a cross-section of the processing module 500E taken along the virtual plane A-A is viewed in the +Y direction is schematically illustrated. The virtual plane A-A is a virtual plane parallel to the X-Z plane.

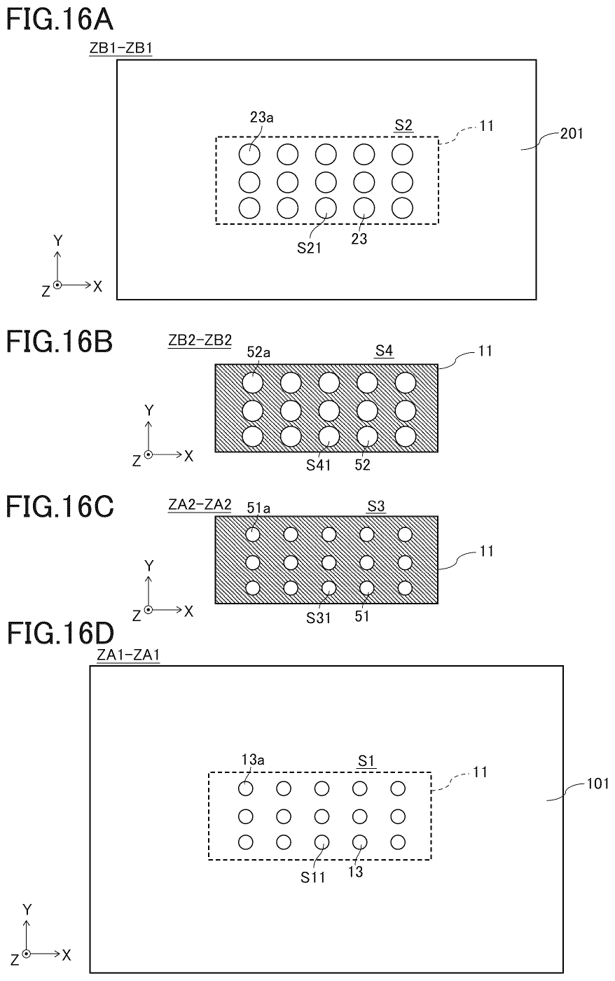

FIG. 16A is a section view of the wiring board 201 according to the fifth embodiment. FIG. 16B is a section view of the wiring member 11 according to the fifth embodiment. FIG. 16C is a section view of the wiring member 11 according to the fifth embodiment. FIG. 16D is a section view of the wiring board 101 according to the fifth embodiment. FIG. 16A schematically illustrates the wiring board 201 in a case where a cross-section of the wiring board 201 taken along a virtual plane ZB1-ZB1 illustrated in FIG. 15 is viewed in the −Z direction. FIG. 16B schematically illustrates the wiring member 11 in a case where a cross-section of the wiring member 11 taken along a virtual plane ZB2-ZB2 illustrated in FIG. 15 is viewed in the −Z direction. FIG. 16C schematically illustrates the wiring member 11 in a case where a cross-section of the wiring member 11 taken along a virtual plane ZA2-ZA2 illustrated in FIG. 15 is viewed in the −Z direction. FIG. 16D schematically illustrates the wiring board 101 in a case where a cross-section of the wiring board 101 taken along a virtual plane ZA1-ZA1 illustrated in FIG. 15 is viewed in the −Z direction.

In the fifth embodiment, the pads 52b and 23b and the bonding members 24b illustrated in the first embodiment are not provided. That is, all of the plurality of pads 13 are pads 13a, all of the plurality of pads 51 are pads 51a, all of the plurality of pads 23 are pads 23a, all of the plurality of pads 52 are pads 52a, all of the plurality of bonding members 14 are bonding members 14a, and all of the plurality of bonding members 24 are pads 24a.

For example, the plurality of pads 13a are all formed in the same size. In addition, for example, the plurality of pads 23a are all formed in the same size. In addition, the size of each pad 23a is larger than the size of each pad 13a. That is, the area S21 of each pad 23a is larger than the area S11 of each pad 13a.

To be noted, although the plurality of pads 13a are all formed in the same size as an example, the configuration is not limited to this, and the plurality of pads 13a may be formed in different sizes. In addition, although the plurality of pads 23a are all formed in the same size as an example, the configuration is not limited to this, and the plurality of pads 23a may be formed in different sizes.

For example, the plurality of pads 51a are all formed in the same size. In addition, for example, the plurality of pads 52a are all formed in the same size. In addition, the size of each pad 52a is larger than the size of each pad 51a. That is, the area S41 of each pad 52a is larger than the area S31 of each pad 51a.

To be noted, although the plurality of pads 51a are all formed in the same size as an example, the configuration is not limited to this, and the plurality of pads 51a may be formed in different sizes. In addition, although the plurality of pads 52a are all formed in the same size as an example, the configuration is not limited to this, and the plurality of pads 52a may be formed in different sizes.

The plurality of pads 51a of the wiring member 11 are bonded to the plurality of pads 13a of the wiring board 101 via the plurality of bonding members 14a. The plurality of pads 52a of the wiring member 11 are bonded to the plurality of pads 23a of the wiring board 201 via the plurality of bonding members 24a.

In addition, in the fifth embodiment, similarly to the first embodiment, S1<S2 holds. That is, the total area S2 is larger than the total area S1. As a result of the relationship of S1<S2, the wiring board 201 having a relatively low flexural rigidity as compared with the wiring board 101 is reinforced by the plurality of bonding members 24 having a larger bonding area than the plurality of bonding members 14, and thus warpage of the wiring board 201 in the thermal fatigue test is reduced. As a result of this, the reliability of bonding is improved.

In addition, similarly to the first embodiment, S3<S4 holds. That is, the total area S4 is larger than the total area S3. As a result of the relationship of S3<S4, the wiring board 201 having a relatively low flexural rigidity as compared with the wiring board 101 is reinforced by the plurality of bonding members 24 having a larger bonding area than the plurality of bonding members 14, and thus warpage of the wiring board 201 in the thermal fatigue test is reduced. As a result of this, the reliability of bonding is improved.

Further, since the area S21 of each of the plurality of pads 23a is larger than the area S11 of each of the plurality of pads 13a, the wiring board 201 is fixed more strongly, thermal deformation is further reduced, and the reliability of bonding is further improved.

Further, since the area S41 of each of the plurality of pads 52a is larger than the area S31 of each of the plurality of pads 51a, the wiring board 201 is fixed more strongly, thermal deformation is further reduced, and the reliability of bonding is further improved.

### Example 1

Example 1 corresponding to the first embodiment will be described with reference to FIGS. 3, 4A, 4B, and 5A to 5D. The size of the wiring board 101 was set to 50 [mm]×50 [mm], and the size of the wiring board 201 was set to 27 [mm]×16 [mm]. The size of the wiring member 11 was set to 20 [mm]×3.6 [mm]. The electronic components 102a and 102b mounted on the wiring board 201 were each a BGA memory component. The size of each of the electronic component 102a and 102b was 12.4 [mm]×15 [mm]. The pitch between the electronic component 102a and the electronic component 102b in the X direction was set to 0.8 [mm], and the pitch therebetween in the Y direction was set to 0.7 [mm]. In Example 1, the same component was used for both the electronic components 102a and 102b.

The wiring boards 101 and 201 were each formed as a wiring board having a Young's modulus of about 18 [GPa] and constituted by the insulator 41 of FR4 formed from glass epoxy and a wiring layer of Cu. The length W₁ of the wiring board 101 in the X direction was set to 50 [mm], and the thickness H1 of the wiring board 101 was set to 0.9 [mm]. The length W₂ of the wiring board 201 in the X direction was set to 20 [mm], and the thickness H2 of the wiring board 201 was set to 0.7 [mm].

Here, in the case where the Young's modulus of the wiring board is represented by E, the width of the wiring board is represented by W, and the thickness of the wiring board is represented by H, the flexural rigidity K of the wiring board is expressed by E×W×H³/12. To be noted, the lengths in the X direction and the thicknesses of the wiring boards 101 and 201 have relationships of W₁>W₂ and H1>H2.

The flexural rigidity K1 of the wiring board 101 was 0.05467 [N·m²] (18×10⁹ [N·m²]×(50×10⁻³ [m]×(0.9×10⁻³ [m])³)/12). The flexural rigidity K2 of the wiring board 201 was 0.01389 [N·m²] (18×10⁹ [N·m²]×(27×10⁻³ [m]×(0.7×10⁻³ [m])³)/12). That is, comparing the flexural rigidity K1 of the wiring board 101 with the flexural rigidity K2 of the wiring board 201, K1>K2 holds, which shows that the flexural rigidity of the wiring board 201 was lower than the flexural rigidity of the wiring board 101.

The thickness of the wiring member 11 was set to 0.5 [mm]. The diameter of the through hole conductor 12 was set to 0.15 [mm], and the pitch of the through hole conductors 12 was set to 0.4 [mm]. The size (diameter) of the pads 51a and 52a connected to the through hole conductor 12 was set to φ0.23 [mm]. The pads 51a and 52a had an SMD structure.

The size (diameter) of each the plurality of pads 23a of the wiring board 201 was set to φ0.23 [mm]. The number of the plurality of pads 23a was set to 313. The size of each of the plurality of pads 23b that were not connected to the through hole conductors 12 and provided for reinforcement was set to 1.1 [mm]×2.9 [mm]. Two each of the plurality of pads 23b were disposed on the left side and right side of the wiring member 11 in the longitudinal direction (X direction).

In Example 1, the area S21 per pad in the plurality of pads 23a for signals was 0.042 [mm²]. In addition, the area S22 per pad in the plurality of pads 23b for reinforcement was 3.190 [mm²]. As described above, the area S22 of each of the plurality of pads 23b was set to be about 77 times as large as the area S21 of each of the plurality of pads 23a.

The size (diameter) of each the plurality of pads 13a of the wiring board 101 for signals was set to φ0.23 [mm]. The number of the plurality of pads 13a was set to 313. Pads for reinforcement not connected to the through hole conductors 12 were not provided on the wiring board 101. Each of the pads 23a, 23b, and 13a had an SMD structure.

The plurality of pads 51a of the wiring member 11 were bonded to the plurality of pads 13a of the wiring board 101 via the plurality of bonding members 14a. The plurality of pads 52a of the wiring member 11 were bonded to the plurality of pads 23a of the wiring board 201 via the plurality of bonding members 24a.

The total area S1 of part of the plurality of bonding members 14 in contact with the plurality of pads 13 of the wiring board 101 was 13.00 [mm²]. The total area S2 of part of the plurality of bonding members 24 in contact with the plurality of pads 23 of the wiring board 201 was 19.38 [mm²]. That is, S1<S2 held. In Example 1, the total area S2 was set to be larger than the total area S1 by 49%.

In Example 1, S1<S2 holds. That is, the total area S2 is larger than the total area S1. As a result of the relationship of S1<S2, the wiring board 201 having a relatively low flexural rigidity as compared with the wiring board 101 is reinforced by the plurality of bonding members 24 having a larger bonding area than the plurality of bonding members 14, and thus warpage of the wiring board 201 in the thermal fatigue test is reduced. In addition, as a result of the reinforcement of the wiring board 201 having a low flexural rigidity, the stress acting on bonding members 24a positioned at outer peripheral corner portions of the plurality of bonding members 24a can be distributed to bonding members 24a positioned at the center portion of the plurality of bonding members 24a or to the plurality of bonding members 14, thus concentration of the stress on the bonding members 24a positioned at the outer peripheral corner portions can be suppressed, and the reliability of the bonding is improved.

### Example 2

Example 2 corresponding to the second embodiment will be described with reference to FIGS. 9, and 10A to 10D. To be noted, matter that is the same as in Example 1 is not described herein.

The thickness of the wiring member 11 was set to 0.5 [mm]. The wiring member 11 included the plurality of pads 52b and the plurality of conductor patterns 53 formed in end surface through holes for reinforcement. The size of the pad 52b was set to φ1.1 [mm], and the end surface through holes each had a shape obtained by dividing a through hole bored by a drill of φ0.85 [mm] into four. The area per conductor pattern in the plurality of conductor patterns 53 positioned in the side surfaces of the wiring member 11 was set to 0.67 [mm²] (2×π×r×h/4).

The size (diameter) of each of the plurality of pads 23b for reinforcement was set to φ1.1 [mm]. The plurality of pads 23b were disposed at the four outer corners of the wiring member 11 in plan view. In Example 2, the area S21 of each pad in the plurality of pads 23a for signals was 0.042 [mm²]. In addition, the area S22 of each pad in the plurality of pads 23b for reinforcement was 0.95 [mm²]. As described above, the area S22 of each of the plurality of pads 23b was set to about 23 times as large as the area S21 of each of the plurality of pads 23a.

The pads to be bonded to the plurality of pads 51c of the wiring member 11 were not provided on the main surface 1011 of the wiring board 101. That is, the plurality of pads 51c were not bonded to the wiring board 101.

The total area S1 of part of the plurality of bonding members 14 in contact with the plurality of pads 13 of the wiring board 101 was 13.00 [mm²]. The total area S2 of part of the plurality of bonding members 24 in contact with the plurality of pads 23 of the wiring board 201 was 16.81 [mm²]. That is, S1<S2 held. In Example 2, the total area S2 was set to be larger than the total area S1 by 29%.

Here, although a case where the total area S2 is set to be 29% larger than the total area S1 has been described, the total area S2 is preferably larger than the total area S1 by 7% or more and 100% or less. For example, in the case where it is attempted to manufacture the wiring boards 101 and 201 such that the total area S1 is equal to the total area S2, that is, such that the size of each of the plurality of pads 13 is equal to the size of each of the plurality of pads 23, difference of about 7% can be generated between the pads 13 and 23 due to a production error of the pads. Therefore, it is preferable that the total area S2 is larger than the total area S1 by 7% or more. In addition, in the case where the total area S2 is set to be larger than the total area S1 by more than 100%, there is a risk that a problem of a short circuit between pads in the region of the total area S2 arises, and therefore it is preferable that the total area S2 is set to be larger than the total area S1 by 100% or less.

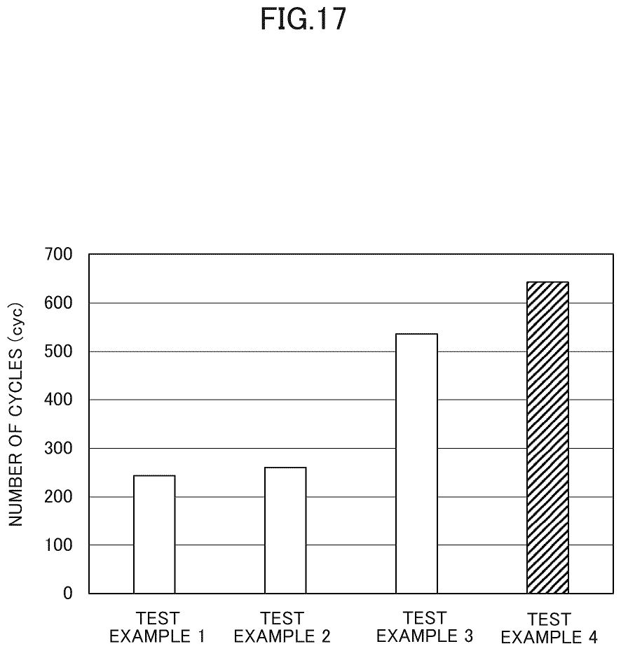

A thermal fatigue test was carried out by using the processing module 500B of Example 2 and a processing module obtained by modifying this. FIG. 17 is a graph illustrating the results of the thermal fatigue test for Test Examples 1 to 4. The vertical axis represents the number of cycles.

The processing module of Test Example 1 had a structure in which the plurality of pads 23b for reinforcement, the plurality of pads 52b, and the plurality of bonding members 24b for reinforcement were omitted from the processing module 500B of Example 2 (no reinforcement pads).

The processing module of Test Example 2 had a structure in which the plurality of pads 13b described in the fourth embodiment, the plurality of pads 51b, and the plurality of bonding members 14b were provided only on the wiring board 101 side in the processing module of Test Example 1 (reinforcement pads on only the lower side).

The processing module of Test Example 3 had a structure in which, in the processing module of Test Example 2, the plurality of pads 13b and the plurality of pads 23b were each formed in the same size such that the total area S1 was equal to the total area S2, the plurality of pads 51b and the plurality of pads 52b were each formed in the same size, the plurality of pads 13b were bonded to the plurality of pads 51b via the plurality of bonding members 14b, and the plurality of pads 23b were bonded to the plurality of pads 52b via the plurality of bonding members 24b (reinforcement pads of the same size on the upper side and the lower side). The processing module of Test Example 4 was the processing module 500B of Example 2.

In the results illustrated in FIG. 17, the breakage of solder is suppressed more in Test Example 2 than in Test Example 1, the breakage of solder is suppressed more in Test Example 3 than in Test Example 2, and the breakage of solder is suppressed more in Test Example 4 than in Test Example 3. The difference between Test Example 1 and Test Example 2 is less than 100 cycles. The difference between Test Example 2 and Test Example 3 is more than 200 cycles. The difference between Test Example 3 and Test Example 4 is more than 100 cycles. From the results illustrated in FIG. 17, it can be seen that the breakage of solder was suppressed for about 400 more cycles in Test Example 4 than in Test Example 1 and for about 100 more cycles in Test Example 4 than in Test Example 3, which shows that high reliability was secured as an electronic device.

### OTHER MODIFICATION EXAMPLES

The present disclosure is not limited to the embodiments described above, and the embodiments can be modified in many ways within the technical concept of the present disclosure. For example, at least two of the plurality of embodiments and plurality of modification examples described above may be combined. In addition, the effects described in the present embodiment are merely enumeration of the most preferable effects that can be obtained from the embodiments of the present disclosure, and the effects of the embodiments of the present disclosure are not limited to those described in the embodiments.

In addition, although a case where the module of the present disclosure is applied to an image pickup device such as a digital camera has been described in the embodiments described above, the configuration is not limited to this. The module of the present disclosure is also applicable to an information device such as a smartphone or a personal computer, and a communication device such as a modem or a router. Alternatively, the module of the present disclosure is also applicable to an office appliance such as a printer or a copier, a medical device such as an X-ray radiographing apparatus or an endoscope, an industrial device such as a robot or a semiconductor device manufacturing apparatus, and a transport device such as a vehicle, an airplane, or a ship.

The disclosure of the present specification includes not only what is explicitly described in the present specification but also all the matter that can be grasped from the present specification and drawings attached to the present specification. In addition, the disclosure of the present specification includes complementary sets of individual concepts described in the present specification. For example, in the case where the present specification includes a description of “A is B”, it can be said that the present disclosure discloses a concept of “A is not B” even if the description of “A is not B” is omitted. This is because description of “A is B” is made on the premise that a case where “A is not B” has been already considered.

As described above, according to the present disclosure, a technique advantageous for improving the reliability of bonding can be provided.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-162633, filed Sep. 19, 2024, which is hereby incorporated by reference herein in its entirety.

What is claimed is:

1. A module comprising:
a wiring member;
a first wiring board; and
a second wiring board laminated on the first wiring board with the wiring member therebetween,
wherein a plurality of first pads bonded to the wiring member via a plurality of first bonding members are disposed on a first main surface of the first wiring board,
wherein a plurality of second pads bonded to the wiring member via a plurality of second bonding members are disposed on a second main surface of the second wiring board,
wherein the second wiring board has a lower flexural rigidity than the first wiring board, and
wherein a total area of part of the plurality of second pads in contact with the plurality of second bonding members is larger than a total area of part of the plurality of first pads in contact with the plurality of first bonding members.

2. The module according to claim 1, wherein the plurality of second pads include two or more second pads that do not overlap with any of the plurality of first pads in a first direction orthogonal to the first main surface.

3. The module according to claim 2,
wherein the two or more second pads each have a larger area than one of the plurality of second pads other than the two or more second pads, and/or
wherein the two or more second pads each have a larger area than one of the plurality of first pads.

4. The module according to claim 1,
wherein the plurality of second pads include two or more second pads that are in contact with at least one of two long sides of a first smallest rectangular region enclosing the plurality of second pads and at least one of two short sides of the first smallest rectangular region,
wherein the two or more second pads each have a larger area than one of the plurality of second pads other than the two or more second pads, and/or
wherein the two or more second pads each have a larger area than one of the plurality of first pads.

5. The module according to claim 1,
wherein the plurality of second pads include second pads of a number larger than a number of first pads in the plurality of first pads, and/or
wherein the plurality of second pads each have a larger area than each of the plurality of first pads.

6. The module according to claim 1, wherein the total area of the part of the plurality of second pads in contact with the plurality of second bonding members is larger than the total area of the part of the plurality of first pads in contact with the plurality of first bonding members by 7% or more and 100% or less.

7. The module according to claim 1,
wherein a plurality of third pads bonded to the first wiring board via the plurality of first bonding members are disposed on a third main surface of the wiring member,
wherein a plurality of fourth pads bonded to the second wiring board via the plurality of second bonding members are disposed on a fourth main surface of the wiring member provided on an opposite side to the third main surface, and
wherein a total area of part of the plurality of fourth pads in contact with the plurality of second bonding members is larger than a total area of part of the plurality of third pads in contact with the plurality of first bonding members.

8. The module according to claim 7, wherein the plurality of fourth pads include two or more fourth pads that do not overlap with any of the plurality of third pads in a first direction orthogonal to the first main surface.

9. The module according to claim 8,
wherein the two or more fourth pads each have a larger area than one of the plurality of fourth pads other than the two or more fourth pads, and/or
wherein the two or more fourth pads each have a larger area than one of the plurality of third pads.

10. The module according to claim 7,
wherein the plurality of fourth pads include two or more fourth pads that are in contact with at least one of two long sides of a second smallest rectangular region enclosing the plurality of fourth pads and at least one of two short sides of the second smallest rectangular region,
wherein the two or more fourth pads each have a larger area than one of the plurality of fourth pads other than the two or more fourth pads, and/or
wherein the two or more fourth pads each have a larger area than one of the plurality of third pads.

11. The module according to claim 7,
wherein the plurality of fourth pads include a first end pad positioned at an end portion of the fourth main surface,
wherein the wiring member includes a conductive pattern that is disposed in a groove in a side surface of the wiring member, the groove being connected to the third main surface and the fourth main surface, and
wherein a second bonding member in contact with the first end pad is in contact with the conductive pattern, the second bonding member being included in the plurality of second bonding members.

12. The module according to claim 11, wherein the first end pad is positioned at a corner portion of the third main surface.

13. The module according to claim 11,
wherein a second end pad not bonded to the first wiring board is disposed at an end portion of the third main surface of the wiring member, and
wherein the conductive pattern is connected to the second end pad.

14. The module according to claim 11,
wherein the plurality of third pads include a second end pad positioned at an end portion of the third main surface, and
wherein a first bonding member in contact with the second end pad is in contact with the conductive pattern, the first bonding member being included in the plurality of first bonding members.

15. The module according to claim 7,
wherein the plurality of fourth pads include fourth pads of a number larger than a number of third pads in the plurality of third pads, and/or
wherein the plurality of fourth pads each have a larger area than each of the plurality of third pads.

16. The module according to claim 1, further comprising a resin member bonding the second wiring board to the wiring member.

17. The module according to claim 1, further comprising:
a first electronic component mounted on a fifth main surface that is a surface of the second wiring board on an opposite side to the second main surface,
wherein the first electronic component overlaps with the wiring member in a first direction orthogonal to the first main surface.

18. The module according to claim 17,
wherein the first electronic component includes a first side surface and a second side surface apart from each other in a second direction intersecting with the first direction, and
wherein the wiring member is disposed between a first virtual plane including the first side surface and a second virtual plane including the second side surface.

19. The module according to claim 1, further comprising:
a first electronic component mounted on a fifth main surface that is a surface of the second wiring board on an opposite side to the second main surface; and
a second electronic component mounted on the fifth main surface of the second wiring board,
wherein the second electronic component is disposed at a position apart from the first electronic component in a third direction intersecting with a first direction orthogonal to the first main surface.

20. The module according to claim 1, further comprising:
a first electronic component mounted on a fifth main surface that is a surface of the second wiring board on an opposite side to the second main surface; and
a second electronic component mounted on the fifth main surface of the second wiring board,
wherein the first electronic component and the second electronic component overlap with the wiring member in a first direction orthogonal to the first main surface.

21. The module according to claim 1, further comprising:
a first electronic component mounted on a fifth main surface that is a surface of the second wiring board on an opposite side to the second main surface;
a second electronic component mounted on the fifth main surface of the second wiring board; and
a third electronic component mounted on the first wiring board,
wherein the first electronic component is a storage device,
wherein the second electronic component is a storage device, and
wherein the third electronic component is a processing device.

22. The module according to claim 1,
wherein a thickness of the second wiring board in a first direction orthogonal to the first main surface is smaller than a thickness of the first wiring board in the first direction, and/or
wherein a length of the second wiring board in a third direction intersecting with the first direction is smaller than a length of the first wiring board in the third direction.

23. The module according to claim 22, wherein the third direction is a longitudinal direction of the second wiring board.

24. An electronic device comprising:
a casing; and
the module according to claim 1 disposed inside the casing,
wherein E₁×W₁×H₁³>E₂×W₂×H₂³ is satisfied, where E₁ represents a Young's modulus of the first wiring board, H₁ represents a thickness of the first wiring board in a first direction orthogonal to the first main surface, W₁ represents a length of the first wiring board in a third direction intersecting with the first direction, E₂ represents a Young's modulus of the second wiring board, H₂ represents a thickness of the second wiring board in the first direction, and W₂ represents a length of the second wiring board in the third direction.

25. An electronic device comprising:
a casing;
a first module disposed inside the casing;
a second module disposed inside the casing; and
a wiring component electrically interconnecting the first module and the second module,
wherein the first module is the module according to claim 1, and
wherein the second module includes an image sensor.
